(19) United States
(12) Patent Application Publication
(10) Pub. No.: US 2020/0294728 A1
(43) Pub. Date: Sep. 17, 2020

(54) PEROVSKITE DEVICES AND METHODS OF MAKING THE SAME

(71) Applicant: Alliance for Sustainable Energy, LLC, Golden, CO (US)

(72) Inventors: Kai ZHU, Littleton, CO (US); Mengjin YANG, Lakewood, CO (US); Talysa Renae KLEIN, Bailey, CO (US); Marinus Franciscus Antonius Maria van HEST, Lakewood, CO (US); Zhen LI, Shanxi (CN)

(21) Appl. No.: 16/649,202

(22) PCT Filed: Oct. 4, 2018
(86) PCT No.: PCT/US18/54370

§ 371 Date: Mar. 20, 2020

Related U.S. Application Data
(60) Provisional application No. 62/567,826, filed on Oct. 4, 2017.

(51) Int. Cl. H01G 9/20; H01L 51/42

(52) U.S. Cl. CPC H01G 9/2081; H01G 9/2031; H01G 9/2009; H01L 51/4253

(57) ABSTRACT

The present disclosure relates to a perovskite-containing solar cell module that includes a glass substrate; a first cell; and a second cell, where each cell includes, in order, a first contact layer that includes fluorine-doped tin oxide, positioned on the substrate, and having an outside surface and a first thickness; an electron transfer layer that includes TiO₂ and having a second thickness between 1 nm and 10 μm; an active layer that includes the perovskite and having a third thickness; a hole transfer layer that includes spiro-OMeTAD and having a fourth thickness; and a second contact layer that includes copper and having a fifth thickness. In addition, the first cell and the second cell are electrically connected by a first gap filled with the copper, and the first gap passes through the third thickness, the fourth thickness, and substantially through the second thickness to terminate at the outside surface.

### CROSS-REFERENCE TO RELATED APPLICATIONS

This application claims the benefit of U.S Provisional Patent Application No. 62/567,826 filed Oct. 4, 2017, the contents of which are incorporated herein by reference in their entirety.

### CONTRACTUAL ORIGIN

The United States Government has rights in this disclosure under Contract No. DE-AC36-08GO₂₈₃₀₈ between the United States Department of Energy and Alliance for Sustainable Energy, LLC, the Manager and Operator of the National Renewable Energy Laboratory.

### BACKGROUND

Perovskite materials, for example organic-inorganic halide perovskites, have drawn tremendous attention in recent years as promising candidates for the next generation of low-cost photovoltaics (PV). The power conversion efficiency (PCE) of perovskite solar cells (PSCs) has rapidly surged from <4% to 22.1% (certified), rivaling conventional thin film PV materials, such as CdTe and CIGS. Perovskites' high performance may originate from many of these materials' excellent optoelectronic properties, such as high absorption coefficient, low defect density and defect tolerance, long carrier lifetime, and advantageous diffusion length. More importantly, high performance PSCs can be fabricated through low cost solution processes. Indeed, PSCs are the first solution-processed solar cells that exceed the 20% efficiency benchmark. With continuous improvements in performance, stability and scaling-up of PSCs, their potential to revolutionize the PV industry is becoming more realistic than ever.

Despite this progress in cell efficiency, most researches have focused on lab-scale, e.g. small-area devices (<1 cm²), fabricated by spin coating. Thus, there remains significant need for the development of practical manufacturing methods for the full-scale production of large-area solar modules that integrate multiple sub-cells. There exists a gap between the lab-scale small-area devices and the large-area solar modules, as the spin coating process is not designed for uniform coating over large size substrates. Developing scalable deposition processes for scaling up the PSCs are essential for their practical applications and commercial adaption.

### SUMMARY

An aspect of the present disclosure is a perovskite-containing solar cell module that includes a glass substrate; a first cell; and a second cell, where each cell includes, in order, a first contact layer that includes fluorine-doped tin oxide, positioned on the substrate, and having an outside surface and a first thickness; an electron transfer layer that includes TiO₂ and having a second thickness between 1 nm and 10 μm; an active layer that includes the perovskite and having a third thickness; a hole transfer layer that includes spiro-OMeTAD and having a fourth thickness; and a second contact layer that includes copper and having a fifth thickness. In addition, the first cell and the second cell are electrically connected by a first gap filled with the copper, and the first gap passes through the third thickness, the fourth thickness, and substantially through the second thickness to terminate at the outside surface.

An aspect of the present disclosure is a perovskite-containing solar cell module that includes a substrate having a first surface; a first cell; and a second cell, where each cell includes, in order, a first contact layer that includes a first material, positioned on the substrate, and having a second surface and a first thickness; an electron transfer layer (ETL) that includes a second material and having a second thickness; an active layer that includes the perovskite and having a third thickness; a hole transfer layer (HTL) that includes a third material and having a fourth thickness; and a second contact layer that includes a fourth material and having a fifth thickness. In addition, the first cell and the second cell are electrically connected by a first gap filled with the fourth material, and the first gap passes through the third thickness, the fourth thickness, and substantially through the second thickness to terminate at the second surface.

In some embodiments of the present disclosure, the module may further include a second gap filled with the second material, where the second gap passes substantially through the first thickness to terminate at the first surface, and the second gap separates the first contact of the first cell from the first contact of the second cell. In some embodiments of the present disclosure, the module may further include a third gap, where the third gap passes through fourth thickness, the third thickness, and substantially through the second thickness to terminate at the second surface, and the third gap separates the second contact of the first cell from the second contact of the second cell. In some embodiments of the present disclosure, the module may further include an insulating layer that includes a fifth material and positioned on the second contact layer, where the second contact layer is positioned between the insulating layer and the HTL, the insulating layer is not electrically conductive, and the fifth material fills the third gap.

In some embodiments of the present disclosure, the perovskite may be defined by ABX₃, where A is a first cation, B is a second cation, and X is an anion. In some embodiments of the present disclosure, the perovskite may include at least one of MAPbI₃ and/or MAₓFA₁₋ₓPbI₃, wherein x is between zero and one, inclusively. In some embodiments of the present disclosure, the first material may include at least one of a metal nanowire, a carbon nanotube, a transparent conducting oxide, graphene, and/or PEDOT:PSS. In some embodiments of the present disclosure, the second material may include at least one of TiO₂, ZnO, SnO₂, BaSnO₃, and/or SrTiO₃. In some embodiments of the present disclosure, the ETL may have a thickness between 5 nm and 10 μm, inclusively.

In some embodiments of the present disclosure, the ETL may include a compact layer and a mesoporous layer, and the compact layer may be positioned between the mesoporous layer and the first contact layer. In some embodiments of the present disclosure, the third material may include at least one of spiro-OMeTAD, PTAA, NiO, CuSCN, CuPc, CuI, a graphene oxide, a carbon nanotube, and/or any suitable organic material. In some embodiments of the present disclosure, the fourth material may include at least one of gold, silver, copper, aluminum, nickel, chromium, a molybdenum oxide, a carbon nanotube, graphene, and/or a transparent conducting oxide. In some embodiments of the present disclosure, the second contact layer may have a thickness between 1 nm and 10 μm, inclusively. In some embodiments of the present disclosure, the fifth material may include a polymer.

An aspect of the present disclosure is a method for manufacturing a solar cell module, where the method includes a first applying of a first solution of an electron transfer layer (ETL) precursor onto a first surface of a first contact layer having a first thickness, where the first applying results in a first liquid film on the first surface, the first liquid film transforms into the ETL that includes a first solid material and having a second surface, and the first applying is performed using at least one of spin coating, spray coating, blade coating, slot-die coating, inkjet printing, screen printing, electrodeposition, sputtering, evaporation, pulsed laser deposition, chemical vapor deposition, and/or atomic layer deposition. In some embodiments of the present disclosure, the first applying may be performed by spray coating. In some embodiments of the present disclosure, the first applying may be performed by spray pyrolysis. In some embodiments of the present disclosure, during the first applying, the first surface may be at a temperature between 300° C. and 600° C. In some embodiments of the present disclosure, the ETL precursor may include titanium diisopropoxide bis(acetylacetonate).

### BRIEF DESCRIPTION OF THE DRAWINGS

Exemplary embodiments are illustrated in referenced figures of the drawings. It is intended that the embodiments and figures disclosed herein are to be considered illustrative rather than limiting.

FIGS. 1A, 1B, and 1C illustrate the structure of a perovskite, according to some embodiments of the present disclosure.

FIGS. 2A and 2B illustrate a non-ideal module and an ideal module, respectively, including at least two cells connected in series, where each cell includes perovskite layer (e.g. an organic-inorganic halide perovskite layer), according to some embodiments of the present disclosure.

FIG. 3 illustrates a method for producing a module that approaches the ideal module illustrated in FIG. 2B, according to some embodiments of the present disclosure.

FIG. 4A illustrates the impact of controlling the spray volume of TiO₂ precursor solution on the TiO₂ layer thickness, according to some embodiments of the present disclosure. Panels (a)-(e) illustrate cross-section SEM images for the compact TiO₂ films coated with different amounts of spray volumes of the TiO₂ precursor solution.

FIG. 4B illustrates the scaling behavior of the TiO₂ film thickness with the spray volume of the TiO₂ precursor solution, according to some embodiments of the present disclosure. With this scaling dependence, it is possible to estimate the TiO₂ film thickness that is less than 20 nm and difficult to determine from the SEM images.

FIG. 5A illustrates typical photocurrent-voltage (J-V) curves of 4-cell perovskite solar modules as a function of TiO₂ film thickness (electron transport layer or ETL) from about 10 nm to 100 nm, according to some embodiments of the present disclosure. The inset shows a picture of a 4-cell module with ˜10.36 cm² aperture area.

FIG. 5B illustrates stabilized power outputs (SPO) of the perovskite solar modules of FIG. 5A, measured near the maximum power points under continuous one-sun illumination, according to some embodiments of the present disclosure.

FIGS. 5C-5F illustrate comparisons of the impacts of TiO₂ film thickness on several PV parameters of small cells (˜0.1 cm² active area) and 4-cell modules, according to some embodiments of the present disclosure: FIG. 5C power conversion efficiency (PCE); FIG. 5D short-circuit photocurrent density (J_{sc}); FIG. 5E fill factor (FF); and FIG. 5F open-circuit voltage (V_{oc}). In FIGS. 5D and 5F, the J_{sc} and V_{oc} values for the 4-cell modules are shown on the per cell basis for comparison purpose.

FIG. 6 illustrates a blade-coated perovskite thin film on 1.5″×2″ substrate, according to some embodiments of the present disclosure.

FIG. 7 illustrates a microscopy image of typical P1, P2, and P3 patterning lines (gaps), similar to the ideal module shown in FIG. 2B, according to some embodiments of the present disclosure. In this example, gap widths of P1 (Reference Number 290), P2 (280), and P3 (270) were about 32 μm, 260 μm, and 62 μm, respectively. The distance between P1 and P3 was about 0.89 mm and the individual cell width was 7 mm, leading to the example module's geometrical fill factor (GFF) of about 87.3%.

FIG. 8 the impact of the TiO₂ film thickness (ETL) on the interconnection contact behavior in perovskite solar modules measured under one-sun illumination, for modules approaching the ideal case of FIG. 2B, according to some embodiments of the present disclosure.

FIG. 9A compares SEM images of blade-coated MAPbI₃ (Panel (a)) and MA_{0.7}FA_{0.3}PbI₃, (Panel (b)) perovskite films, according to some embodiments of the present disclosure.

FIG. 9B compares time-resolved photoluminescence (TRPL) lifetime measurements on perovskite thin films, MAPbI₃ and MA_{0.7}FA_{0.3}PbI₃, deposited on glass substrates, according to some embodiments of the present disclosure.

FIG. 9C compares the J-V curves of perovskite thin films, MAPbI₃ and MA_{0.7}FA_{0.3}PbI₃, deposited on glass substrates, for modules approaching the ideal case of FIG. 2B, according to some embodiments of the present disclosure.

FIG. 9D compares the external quantum efficiency (EQE) spectra of PSCs based on MAPbI₃ and MA_{0.7}FA_{0.3}PbI₃ thin films, for modules approaching the ideal case of FIG. 2B, according to some embodiments of the present disclosure.

FIG. 10A illustrates an SEM image of the device stack consisting of blade-coated perovskite as well as blade-coated spiro-OMeTAD-based HTL, according to some embodiments of the present disclosure.

FIG. 10B illustrates J-V curves and SPO (inset) of the best four-cell perovskite solar module with ˜10.36 cm² aperture area, for modules approaching the ideal case of FIG. 2B, according to some embodiments of the present disclosure.

FIG. 11 illustrates a top view SEM image of blade-coated spiro-OMeTAD-based hole transport layer, according to some embodiments of the present disclosure.

FIG. 12A illustrates a photo of a 6-cell perovskite solar module with an aperture area of 26.04 cm² (4.2 cm×6.2 cm), for modules approaching the ideal case of FIG. 2B, according to some embodiments of the present disclosure.

FIG. 12B illustrates a J-V curve with reverse scan and the stabilized power output under continuous one-sun illumination), according to some embodiments of the present disclosure.

FIGS. 13A, 13B, and 13C illustrate contact behavior using various top contact materials: FIG. 13A Cu in dark and FIG. 13B Cu under one sun as well as FIG. 13C MoOₓ/Al in dark as the top contact material, according to some embodiments of the present disclosure.

REFERENCE NUMBERS

| | |
|---|---|
| 100 | perovskite |
| 110 | cation A |
| 120 | cation B |
| 130 | anion X |
| 200 | module |
| 202 | cell |
| 204 | interconnection |
| 210 | substrate |
| 220 | first contact layer |
| 230 | electron transport layer (ETL) |
| 240 | perovskite layer |
| 250 | hole transport layer (HTL) |
| 260 | second contact layer |
| 270 | empty gap |
| 280 | contact layer filled gap |
| 290 | ETL filled gap |
| 300 | method |
| 310 | depositing of a first contact layer |
| 312 | first intermediate module |
| 315 | forming of a first gap |
| 317 | second intermediate module |
| 320 | depositing of an ETL |
| 325 | third intermediate module |
| 330 | depositing of a perovskite layer |
| 335 | first treating |
| 337 | fourth intermediate module |
| 340 | depositing of a HTL |
| 342 | second treating |
| 344 | fifth intermediate module |
| 345 | forming of second gap |
| 347 | sixth intermediate module |
| 350 | depositing of second contact layer |
| 352 | seventh intermediate module |
| 355 | forming of third gap |
| 360 | final target module |

### DETAILED DESCRIPTION

The present disclosure may address one or more of the problems and deficiencies of the prior art discussed above. However, it is contemplated that some embodiments as disclosed herein may prove useful in addressing other problems and deficiencies in a number of technical areas. Therefore, the embodiments described herein should not necessarily be construed as limited to addressing any of the particular problems or deficiencies discussed herein.

The present disclosure relates to PSCs suitable for full-scale use (e.g. industrial and/or commercial) and methods for manufacturing these PSCs. Large-area PSCs can be separated into smaller area sub-cells, which may then be series interconnected to form a solar module. The solar module integration avoids long distance charge transport in TCO substrates, thus reducing parasitic resistive losses. Solar module integration also increases the photo-voltage available from the modules. There are at least two approaches to constructing a solar module on a monolithic substrate. One is to deposit each functioning layer only onto the needed regions, either through a mask guided deposition or pattern-able printing techniques (e.g. screen printing). Another approach is to coat each layer on the entire substrate area and later separate the sub-cells with laser and/or mechanical scribing. Both methods generate “dead” regions depending on the resolution of the patterning or scribing methods used. The ratio of active area to substrate area is referred to as the geometric fill factor (GFF) of the module, with a higher GFF meaning a smaller dead area power loss due to the module integration. The first approach usually creates wider gap distances between sub-cells due to the lower resolution compared to the gap distances that can be achieved using laser scribing. The wider gap distances may result in erosion of the module's active area and reduced GFF of the modules.

One major difference between large-area solar modules (e.g. full-scale) and small-area single cells (e.g. lab-scale) is the contacts connecting individual sub-cells. Developing procedures to scribe sub-cells and make reliable and effective interconnections between them are of critical importance to fabricate large-scale solar modules with efficiencies as high as those demonstrated in single cells. Thus, the present disclosure demonstrates a fully scalable manufacturing method for perovskite module fabrication. In some embodiments of the present disclosure, a TiO₂ electron transport layer (ETL) may be deposited using spray pyrolysis, with both a perovskite absorber layer and a spiro-OMeTAD hole transport layer (HTL) deposited using blade coating. The influence of TiO₂ ETL thickness on the resistance of metal/TiO₂/TCO interconnections in the resultant perovskite modules are described herein. The optimized ETL thickness to balance shunting and interconnection resistance is identified. With optimizations on the ETL thickness, blade coating HTL, and perovskite composition, an aperture PCE of 15.6% and an aperture area of 10.36 cm² was achieved for a 4-cell perovskite module, with the cells in series, with gaps (the result of scribing) separating the individual cells from one another. This example is among the highest efficiencies of perovskite solar modules fabricated by scalable deposition methods.

The term “spray pyrolysis” refers in general to a process in which thins films may be deposited by spraying a solution containing precursors onto a heated surface, where the precursors react and/or thermally degrade to form the desired films, for example TiO₂. In some embodiments of the present disclosure, the precursors for forming TiO₂ (titanium diisopropoxide bis(acetylacetonate) in a 1-butanol solution) may be sprayed onto a heated substrate (e.g. glass) that is at a temperature between 300° C. and 600° C., or between 400° C. and 550° C. Further, the terms “mesoporous” layers and “compact” layers refer to the presence or absence, respectively, of pores in the layers. In some embodiments of the present disclosure, a mesoporous TiO₂ film (e.g. ETL film) may be formed from a plurality of interconnected TiO₂ nanoparticles having a characteristic length between 50 nm and 100 nm, wherein the interconnected nanoparticles also contain interstitial spaces, or pores, resulting in an overall empty volume in the film between 50% and 70%. In contrast, a compact TiO₂ film, formed for example by vapor phase deposition, has an overall empty pore volume equal to zero percent, or approaching zero percent.

Thus, in some embodiments of the present disclosure, one or more layers (e.g. a perovskite layer and/or a HTL) of a solar cell module may be deposited by blade coating. Blade coating may be performed at a speed between 0.05 meters/minute and 1000 m/min, or between 0.25 m/min and 300 m/min. Further, blade coating may be performed at a height between 40 μm and 400 μm, or between 25 μm and 200 μm. In some embodiments of the present disclosure, blade coating may apply a liquid precursor such that the applied liquid film has a wet film thickness between 1 μm and 20 μm, corresponding to a liquid precursor application rate between 1 ml/m² and 20 ml/m², or between 0.1 ml/m² and 50 ml/m².

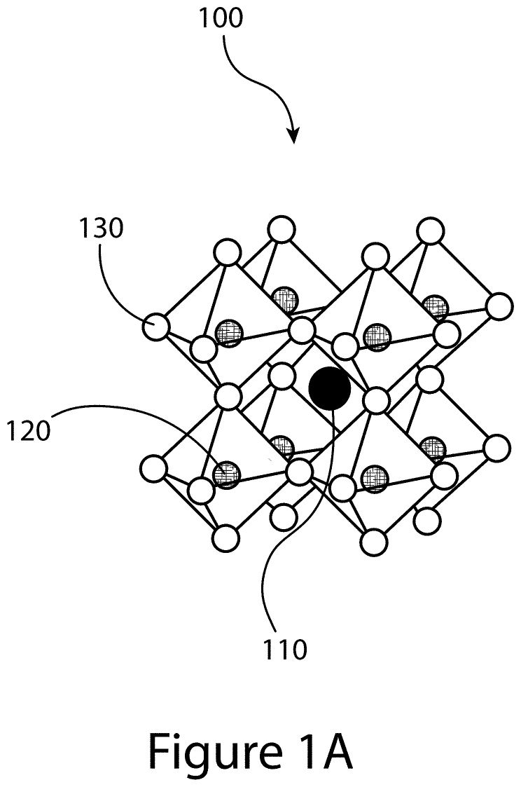

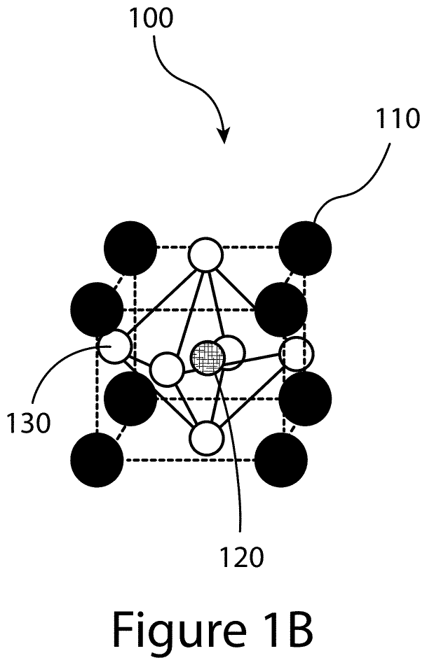

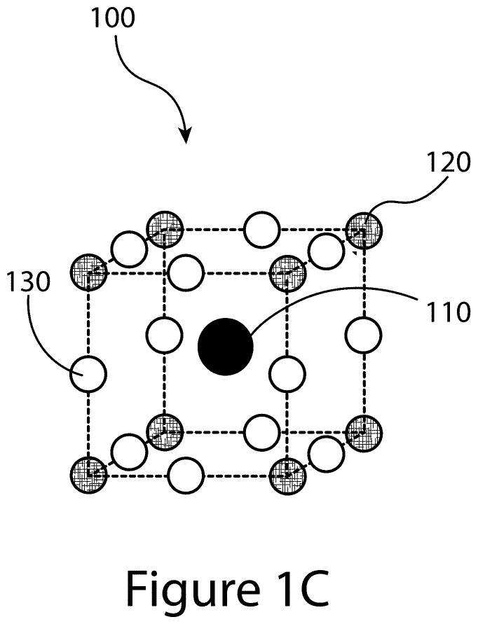

FIGS. 1A, 1B, and 1C illustrate that perovskites 100, for example organic-inorganic halide perovskites, may organize into cubic crystalline structures with corner-sharing octahedra, as well as other crystalline structures such as tetragonal, hexagonal, and orthorhombic with either edge- or face-sharing octahedra, and may be described by the general formula ABX₃, where X (130) is an anion and A (110) and B (120) are cations, typically of different sizes (A typically larger than B). FIG. 1A illustrates that a perovskite 100 may be organized into eight octahedra surrounding a central A-cation 110, where each octahedra is formed by six X-anions 130 surrounding a central B-cation 120. FIG. 1B illustrates that a perovskite 100 may be visualized as a cubic unit cell, where the B-cation 120 is positioned at the center of the cube, an A-cation 110 is positioned at each corner of the cube, and an X-anion 130 is face-centered on each face of the cube. FIG. 1C illustrates that a perovskite 100 may also be visualized as a cubic unit cell, where the B-cation 120 resides at the eight corners of a cube, while the A-cation 110 is located at the center of the cube and with 12 X-anions centrally located between B-cations along each edge of the unit cell. For both unit cells illustrated in FIGS. 1B and 1C, the A-cations 110, the B-cations 120, and the X-anions 130 balance to the general formula ABX₃, after accounting for the fractions of each atom shared with neighboring unit cells. For example, referring to FIG. 1B, the single B-cation 120 atom is not shared with any of the neighboring unit cells. However, each of the six X-anions 130 is shared between two unit cells, and each of the eight A-cations 110 is shared between eight unit cells. So, for the unit cell shown in FIG. 1B, the stoichiometry simplifies to B=1, A=8*0.124=1, and X=6*0.5=3, or ABX₃. Similarly, referring again to FIG. 1C, since the A-cation is centrally positioned, it is not shared with any of the unit cells neighbors. However, each of the 12 X-anions 130 is shared between four neighboring unit cells, and each of the eight B-cations 120 is shared between eight neighboring unit cells, resulting in A=1, B=8 *0.125=1, and X=12*0.25=3, or ABX₃. Referring again to FIG. 1C, the X-anions 130 and the B-cations 120 are shown as aligned along an axis; e.g. where the angle at the X-anion 130 between two neighboring B-cations 120 is exactly 180 degrees, referred to herein as the tilt angle. However, a perovskite 100 may have may have a tilt angle not equal to 180 degrees. For example, some embodiments of the present disclosure may have a tilt angle between 153 and 180 degrees.

Typical inorganic perovskites include calcium titanium oxide (calcium titanate) minerals such as, for example, CaTiO₃ and SrTiO₃. In some embodiments of the present invention, the A-cation 110 may include a nitrogen-containing organic compound such as an alkyl ammonium compound. The B-cation 120 may include a metal and the X-anion 130 may include a halogen. Additional examples for the A-cation 110 include organic cations and/or inorganic cations, for example Cs, Rb, K, Na, Li, and/or Fr. Organic A-cations 110 may be an alkyl ammonium cation, for example a C₁₋₂₀ alkyl ammonium cation, a C₁₋₆ alkyl ammonium cation, a C₂₋₆ alkyl ammonium cation, a C₁₋₅ alkyl ammonium cation, a C₁₋₄ alkyl ammonium cation, a C₁₋₃ alkyl ammonium cation, a C₁₋₂ alkyl ammonium cation, and/or a C₁ alkyl ammonium cation. Further examples of organic A-cations 110 include methylammonium (CH₃NH³⁺), ethylammonium (CH₃CH₂NH³⁺), propylammonium (CH₃CH₂ CH₂NH³⁺), butylammonium (CH₃CH₂ CH₂ CH₂NH³⁺), formamidinium (NH₂CH═NH²⁺), hydrazinium, acetylammonium, dimethylammonium, imidazolium, guanidinium and/or any other suitable nitrogen-containing or organic compound. In other examples, an A-cation 110 may include an alkylamine. Thus, an A-cation 110 may include an organic component with one or more amine groups. For example, an A-cation 110 may be an alkyl diamine halide such as formamidinium (CH(NH₂)₂). Thus, the A-cation 110 may include an organic constituent in combination with a nitrogen constituent. In some cases, the organic constituent may be an alkyl group such as straight-chain or branched saturated hydrocarbon group having from 1 to 20 carbon atoms. In some embodiments, an alkyl group may have from 1 to 6 carbon atoms. Examples of alkyl groups include methyl (C₁), ethyl (C₂), n-propyl (C₃), isopropyl (C₃), n-butyl (C₄), tert-butyl (C₄), sec-butyl (C₄), iso-butyl (C₄), n-pentyl (C₅), 3-pentanyl (C₅), amyl (C₅), neopentyl (C₅), 3-methyl-2-butanyl (C₅), tertiary amyl (C₅), and n-hexyl (C₆). Additional examples of alkyl groups include n-heptyl (C₇), n-octyl (C₈) and the like.

Examples of metal B-cations 120 include, for example, lead, tin, germanium, and or any other 2+ valence state metal that can charge-balance the perovskite 100. Further examples include transition metals in the 2+ state such as Mn, Mg, Zn, Cd, and/or lanthanides such as Eu. B-cations may also include elements in the 3+ valence state, as described below, including for example, Bi, La, and/or Y. Examples for X-anions 130 include halogens: e.g. fluorine, chlorine, bromine, iodine and/or astatine. In some cases, a perovskite may include more than one X-anion 130, for example pairs of halogens; chlorine and iodine, bromine and iodine, and/or any other suitable pairing of halogens. In other cases, the perovskite halide 100 may include two or more halogens of fluorine, chlorine, bromine, iodine, and/or astatine.

Thus, the A-cation 110, the B-cations 120, and X-anion 130 may be selected within the general formula of ABX₃ to produce a wide variety of perovskites 100, including, for example, methylammonium lead triiodide (CH₃NH₃PbI₃), and mixed halide perovskites such as CH₃NH₃PbI₃₋ₓClₓ and CH₃NH₃PbI₃₋ₓBrₓ. Thus, a perovskite 100 may have more than one halogen element, where the various halogen elements are present in non-integer quantities; e.g. x is not equal to 1, 2, or 3. In addition, perovskites can form three-dimensional (3-D), two-dimensional (2-D), one-dimensional (1-D) or zero-dimensional (0-D) networks, possessing the same unit structure. As described herein, the A-cation 110 of a perovskite 100, may include one or more A-cations, for example, one or more of cesium, FA, MA, etc. Similarly, the B-cation 120 of a perovskite 100, may include one or more B-cations, for example, one or more of lead, tin, germanium, etc. Similarly, the anion 130 of a perovskite 100 may include one or more anions, for example, one or more halogens. Any combination is possible provided that the charges balance.

For example, a perovskite having the basic crystal structure illustrated in FIG. 1A, in at least one of a cubic, orthorhombic, and/or tetragonal structure, may have other compositions resulting from the combination of the cations having various valence states in addition to the 2+ state and/or 1+ state described above for lead and alkyl ammonium cations; e.g. compositions other than AB²⁺X₃ (where A is one or more cations, or for a mixed perovskite where A is two or more cations). Thus, the methods described herein may be utilized to create novel mixed cation materials having the composition of a double perovskite (elpasolites), A₂B¹⁺B³⁺X₆, with an example of such a composition being Cs₂BiAgCl₆ and Cs₂CuBiI₆. Another example of a composition covered within the scope of the present disclosure is described by A₂B⁴⁺X₆, for example Cs₂PbI₆ and Cs₂SnI₆. Yet another example is described by A₃B₂³⁺X₉, for example Cs₃Sb₂I₉. For each of these examples, A is one or more cations, or for a mixed perovskite, A is two or more cations.

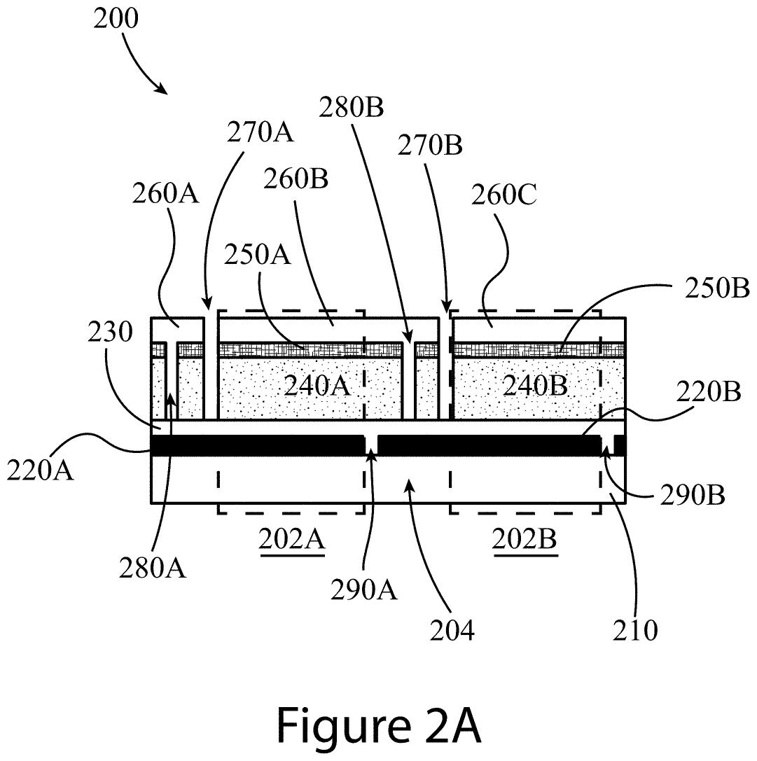

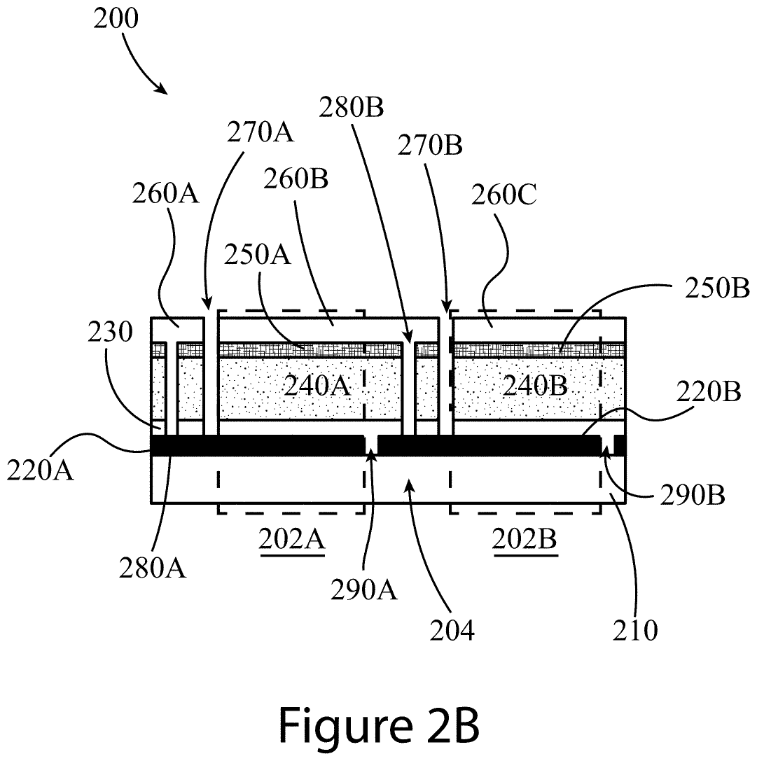

FIGS. 2A and 2B illustrate non-ideal and ideal perovskite-containing modules 200, respectively. Referring to FIG. 2B, an ideal module 200 may include two or more cells (two shown; 202A and 202B) connected in series by an interconnection 204. An interconnection 204 is a physical connection between the second contact layer (e.g. 260B) of a first cell (e.g. 202A) with the first contact layer (e.g. 220B) of a second cell (e.g. 202B). This results in the addition of the voltage produced by each cell (202A and 202B) in the series of cells in the module 200, with the current flowing through each cell remaining constant.

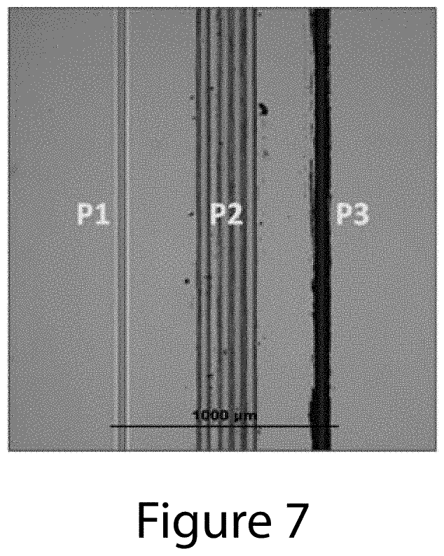

Each cell (202A and 202B) may be positioned on a substrate 210. The substrate 210 may be constructed of any suitable material including at least one of glass, foil and/or plastic. A substrate 210 may have a thickness between several micrometers and several millimeters. A first contact layer 220, for example a transparent conducting oxide (TCO) layer, may be positioned in direct physical contact with the substrate 210. TCOs may include at least one of fluorine-doped tin oxide (FTO), indium-doped tin oxide (ITO), indium zinc oxide (IZO), gallium zinc oxide (GZO), and/or aluminum-doped zinc oxide (AZO). In some embodiments of the present disclosure, a transparent first contact layer 220 may be in the form of at least one of a metal nanowire, a carbon nanotube, a p-type transparent conducting layer, a CuS-based TCO, PEDOT:PSS, and/or a graphene sheet. Gaps (270, 280, and 290) may separate the first contact layer 220 into different sections (e.g. 220A and 220B) corresponding to TCO sections for each respective cell. Each gap (270, 280, and 290) may have a width between about 1 μm and about 1 mm, or between about 5 μm to 250 μm. The module 200 may also include an electron transport layer (ETL) 230 positioned in contact with the first contact layer 220 (e.g. a TCO), such that the first contact layer 220 may be positioned between the substrate 210 and the ETL 230. The ETL 230 shown in FIG. 2B may also fill in the gaps, resulting in the ETL filled gaps (290A and 290B; corresponding to P1 in FIG. 7), where the ETL material extends through the thickness of the first contact layer 220 from the plane occupied by the ETL 230 to the surface of the underlying substrate 210. Referring to the portion of HTL 250 and perovskite layer 240 positioned between the contact layer filled gap 280B and empty gap 270B, this material does not produce any power. Therefore, it is desirable to minimize the width of this material to as small as possible, e.g. approaching zero nanometers.

An ETL 230 may be constructed of at least one of TiO₂, ZnO, SnO₂, BaSnO₃, and/or SrTiO₃, having a thickness between about 5 nm and about 1 μm. In some embodiments of the present disclosure, an ETL 230 may include a first compact layer of these materials and a second mesoporous layer of these materials. Each cell (202A and 202B) of the module 200 may contain a perovskite layer 240, for example an organic-inorganic halide perovskite, as an active layer. So, each cell (202A and 202B) may have its own respective perovskite layer (240A and 240B), positioned in direct physical contact with the underlying ETL 230. The perovskite layer 240 may be constructed of any suitable perovskite having a crystal structure as illustrated in FIGS. 1A-1C and described above.

The ideal example of a module 200, shown in FIG. 2B, may also include a hole transport layer (HTL) 250 positioned in direct physical contact with the perovskite layer 240, such that the perovskite layer 240 may be positioned between the HTL 250 and the ETL 230. The HTL 230 may be constructed of at least one of spiro-OMeTAD, PTAA, NiO, CuSCN, CuPc, graphene oxide, carbon nanotubes, CuI, and/or an organic material having a thickness between about 5 nm and about 1 μm. As shown in FIG. 2B, the perovskite layer 240 and the HTL 250 may be processed to form gaps that separate each into distinct sections for each cell (202A and 202B). So, the perovskite layer 240 may be separated into a first perovskite layer 240A for the first cell 202A and a second perovskite layer 240B for the second cell 202B by at least one gap, where both cells are positioned substantially within the same horizontal plane.

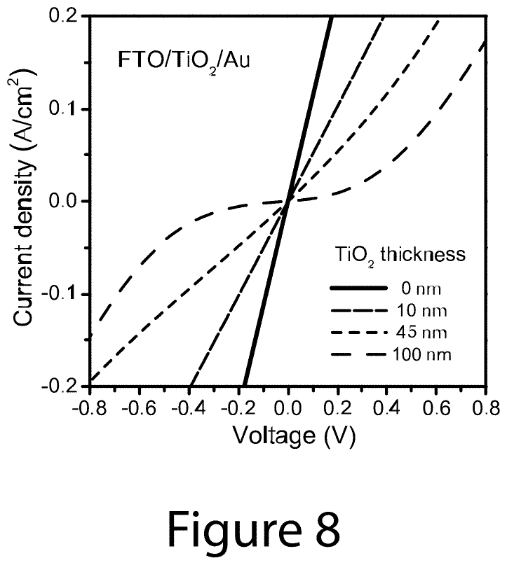

Finally, the ideal module 200, as shown in FIG. 2B, may include a second contact layer 260 positioned in direct physical contact with the HTL 250. The second contact layer 260 may be constructed of any suitable metal and/or conductive oxide, with examples including at least one of gold, Ag, MoOx/Al, Cu, carbon nanotube, graphene, Ni, Cr₂O₃/Cr, and/or TCO, having a thickness between about 1 nm and about 10 μm, or between about 5 nm and about 1 μm. The contact layer 260 may fill in the gaps separating the perovskite layer 240 into different sections (e.g. 240A and 240B), resulting in contact layer filled gaps (280A and 280B). In some embodiments, the contact layer filled gaps (280A and 280B, corresponding to P2 in FIG. 7) may pass perpendicularly through the thickness of the perovskite layer 240 and the thickness of the ETL 230, such that the contact layer filled gaps (280A and 280B) extend from the plane of the second contact layer 260 to the surface of the underlying first contact layer 220. This is beneficial because removal of the ETL 230 enables direct electrical contact of the first contact layer 220 with the second contact layer 260. Otherwise, any remaining ETL material can form a Schottky contact having large contact resistances (see FIG. 8, which demonstrates that as an ETL 230 of TiO₂ thickness is reduced from 100 nm to 10 nm, the I-V curves changed from a Schottky diode behavior (S-shape) to an ohmic behavior (straight line)). Lastly, the ideal module 200 of FIG. 2B may include at least one empty gap (270A and 270B corresponding to P3 in FIG. 7), which traverses perpendicularly across the entire thicknesses of the second contact layer 260 and the HTL 250, and across the perovskite layer 240. Additionally, the empty gaps (270A and 270B) may be filled with an insulating material (not shown) to add structural integrity and environmental protection to the thin film device layers. Referring no to the non-ideal module 200 of FIG. 2A, this module does not have contact layer filled gaps 280, or empty gaps 270 that extend all the way through the HTL 250, the perovskite layer 240, and the ETL 230, to the surface of the underlying first contact layer 220.

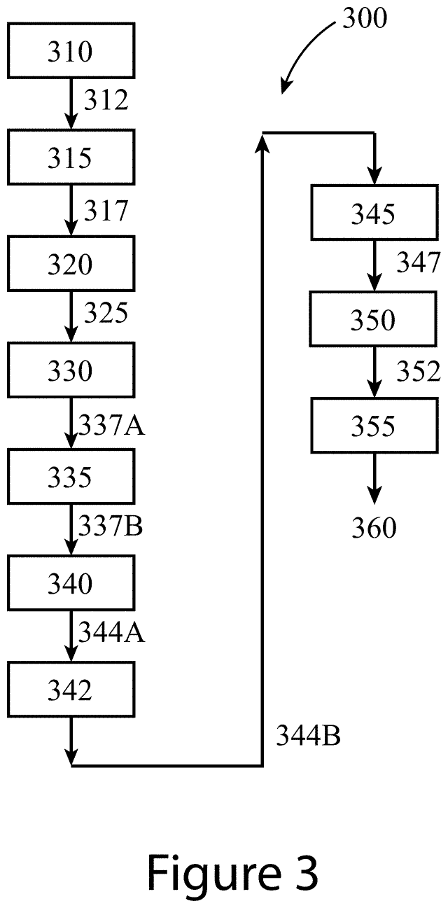

FIG. 3 illustrates an example of a method 300 for producing a module 200 like the modules 200 shown in FIGS. 2A and 2B, with the objective of producing the ideal module 200 of FIG. 2B. The method 300 of this example sequentially produces a module, where the module passes through various intermediate incomplete forms. These intermediate forms are referred to herein as “intermediate modules”. The method 300 may begin with the depositing of a first contact layer 310 (e.g. TCO layer) onto a substrate, resulting in a first intermediate module 312. The depositing of the TCO layer 310 may include at least one of radio frequency sputtering, direct current sputtering, evaporation, and/or spray pyrolysis. The first intermediate module 312 having a first contact layer 220 on a substrate 210 may then be further processed by the forming of a first gap 315 (ETL filled gap 290 of FIG. 2A; P1 of FIG. 7) onto the surface of the first contact layer 220; e.g. by patterning using laser scribing, mechanical etching, and/or chemical etching. Thus, the forming of the first gap 315 may result in a second intermediate module 317 having a patterned first contact layer 220, having one or more first gaps. The second intermediate module 317 may then be processed by the depositing of an ETL 310 onto at least a portion of the first contact layer 220, resulting in the formation of a third intermediate module 325. The depositing of the ETL 320 may be achieved by at least one of spin coating, spray coating, blade coating, slot-die coating, inkjet printing, screen printing, electrodeposition, sputtering, evaporation, PLD, CVD, and/or ALD, at a temperature between about room temperature and about 600° C. During the depositing of the ETL 320, at least some of the first gaps formed during the forming of the first gap 315 may be filled with the ETL 230, resulting in ETL filled gaps 290, such that the ETL 230 penetrates the depth of the first gaps to pass completely pass through the thickness of the first contact layer 220 and physically contact the underlying substrate 210.

Referring again to FIG. 3, the method 300 may then continue with the depositing of a perovskite layer 330 onto the surface of the ETL, resulting in the formation of a fourth intermediate module 337. The depositing of the perovskite layer 330 may be accomplished by a solution processing method, with examples including at least one of spraying, blade coating, curtain coating, dip coating, spin coating, slot-die coating, inkjet printing, screen printing, electrodeposition, evaporation, and/or CVD, at a temperature between about room temperature and about 350° C. The depositing of the perovskite layer 330 may result in a liquid perovskite layer positioned on the ETL 290 and a fourth intermediate module 337A having a liquid layer positioned on its surface. Thus, the liquid perovskite layer, and the fourth intermediate module 337A, may undergo a first treating 335 to convert the liquid perovskite layer to a solid perovskite layer; e.g. by thermal annealing, at a temperature between about room temperature and about 350° C., at a duration between about 10 seconds and about 100 minutes. As a result, the first treating 335 may result in the conversion of the liquid phase perovskite of the fourth intermediate module 337A to a fourth intermediate module 337B having a solid perovskite layer 240 positioned on the ETL.

Referring again to FIG. 3, the fourth intermediate module 337B having a solid perovskite layer 240 may then be processed further by the depositing of a HTL 340 onto the perovskite layer 240. The depositing of the HTL 340 may be accomplished by a solution processing method, with examples including at least one of spraying, blade coating, curtain coating, dip coating, spin coating, slot-die coating, inkjet printing, screen printing, sputtering, evaporation, PLD, CVD, and/or ALD, at a temperature between about room temperature and about 350° C. Like the depositing of a perovskite layer 330, the depositing of the HTL 340 may result in the formation of a fifth intermediate module 344A having a liquid HTL positioned on the perovskite layer. Thus, and the fifth intermediate module 344A having a liquid phase HTL, may undergo a second treating 342 to convert the liquid HTL to a solid HTL 250, resulting in fifth intermediate module 344B; e.g. by thermal annealing at a temperature between about room temperature and about 350° C., at a duration between about 10 seconds and about 100 minutes. As a result, the second treating 342 may result in the formation of a fifth intermediate module 344B having a solid HTL 250 positioned on the solid perovskite layer 240. In some embodiments of the present disclosure, only one treating step may be used to simultaneously convert both a liquid perovskite layer and a liquid HTL to solid forms of each, 240 and 250, respectively.

The fifth intermediate module, having a HTL 250, may then be processed by the forming of a second gap 345 onto the surface of the HTL 250; e.g. patterning by laser scribing, mechanical etching, and/or chemical etching. Thus, the forming of the second gap 345 may result in a sixth intermediate module 347 having a patterned HTL 250, having one or more second gaps. The patterning may completely penetrate the thickness of the HTL 250, the thickness of the underlying perovskite layer 240, and the thickness of the underlying ETL 230. Subsequent to the forming of the second gap 345, the sixth intermediate module 347 having a patterned HTL surface may be processed by the depositing of a second contact layer 350 onto the patterned surface of the HTL 250. The depositing of the second contact layer 350 may be accomplished by at least one of thermal evaporation, spin coating, spray coating, blade coating, slot-die coating, inkjet printing, screen printing, sputtering, PLD, CVD, and/or ALD, at a temperature between about room temperature and about 350° C., resulting in the forming of a seventh intermediate module 352. The second contact layer 260 may completely fill the second gaps, resulting in the ETL filled gaps 290 shown in FIG. 2B, such that the second contact layer 260 is in in direct physical contact with the first contact layer 220.

Finally, the method 300 may conclude with the forming of a third gap 355 (the empty gap 270 of FIG. 2B) onto the seventh intermediate module 352, resulting in a completed final module 360, similar to that shown in FIG. 2B. The third gap, may completely penetrate the thicknesses of each of the second contact layer 260, the HTL 250, the perovskite layer 240, and the ETL 230, such that the third gap passes through the module 200 to the surface of the first contact layer 220. In some embodiments of the present disclosure, the forming of the third gap 355 may be accomplished by laser scribing, mechanical etching, and/or chemical etching. Thus, the forming of the third gap 345 may result in the final module 360 having a patterned contact layer, having one or more third gaps.

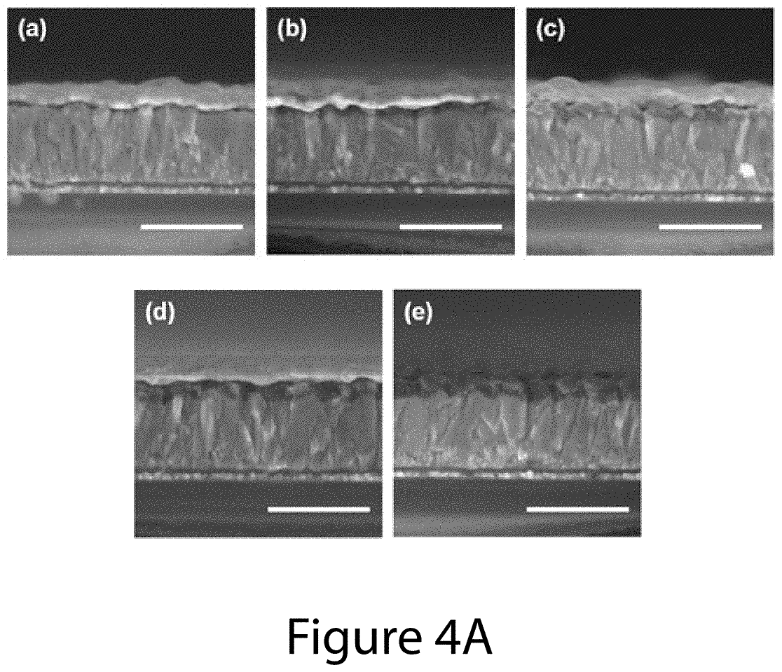

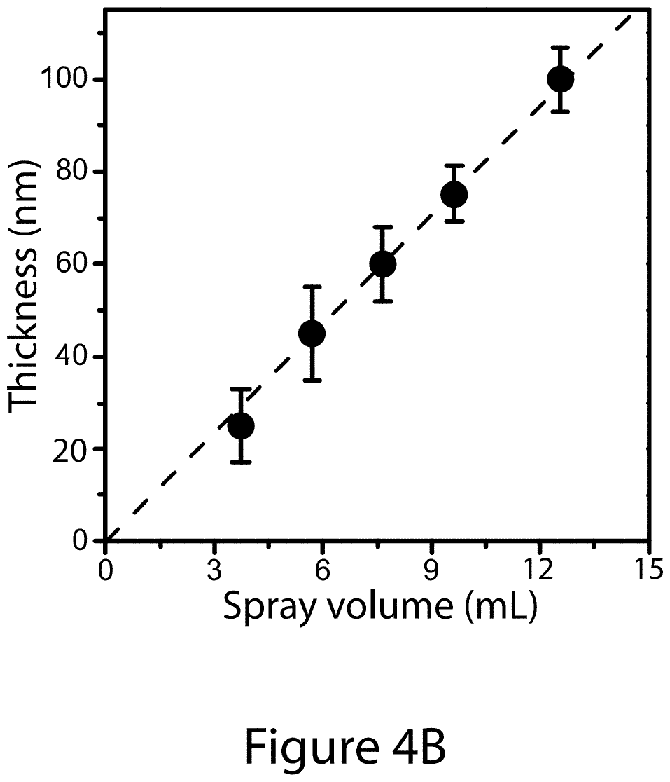

In some embodiments of the present disclosure, a (n-i-p) PSC architecture includes a stack of device layers glass/TCO/ETL/perovskite/HTL/metal, corresponding to substrate/first contact layer/ETL/perovskite layer/HTL/second contact layer. The ETL and the HTL may be constructed of TiO₂ and doped spiro-OMeTAD, respectively. The physical properties of the TiO₂ ETL (e.g., thickness, roughness, porosity, and conductivity) may strongly influence the device performance as well as the hysteresis behavior largely due to the effects of the ETL on the kinetics of electron extraction. In general, an ETL should be pinhole free to minimize shunting and to enable selective/effective extraction and conduction of electrons away from the perovskite layer. The ETL thickness may need to be optimized for high-efficiency PSCs. In some embodiments of the present disclosure, spray-pyrolysis coating may be used to deposit compact TiO₂ (c-TiO₂) ETLs onto a device. In some embodiments of the present disclosure, the thickness of a TiO₂ layer (between 1 nm and 100 nm) may be defined by controlling at least one of the number of coating cycles, the rate of spraying, the concentration of the TiO₂ precursor, and/or the total spray volume of the TiO₂ precursor (see FIGS. 4A and 4B). Described herein, are the impacts of the TiO₂ ETL layer on the characteristics of perovskite-containing modules prepared by blade coating methods using a perovskite ink. In some embodiments of the present disclosure, the ETL precursor (e.g. TiO₂ precursor) may be deposited (e.g. sprayed) onto a surface of a module (e.g. the surface of the first contact layer) at a rate between 0.005 ml/cm² to 0.5 ml/cm².

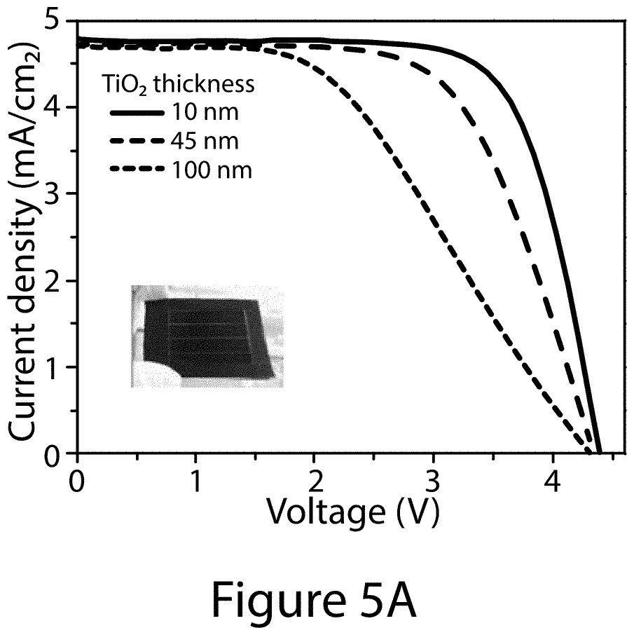

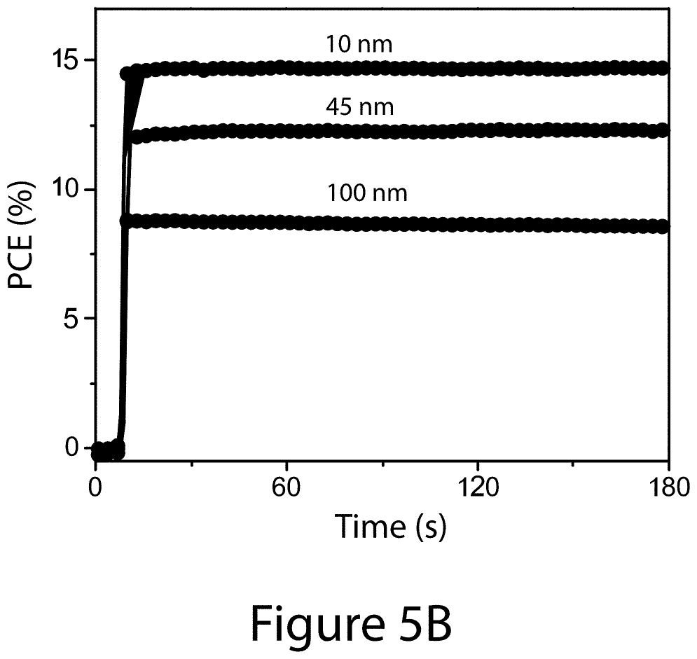

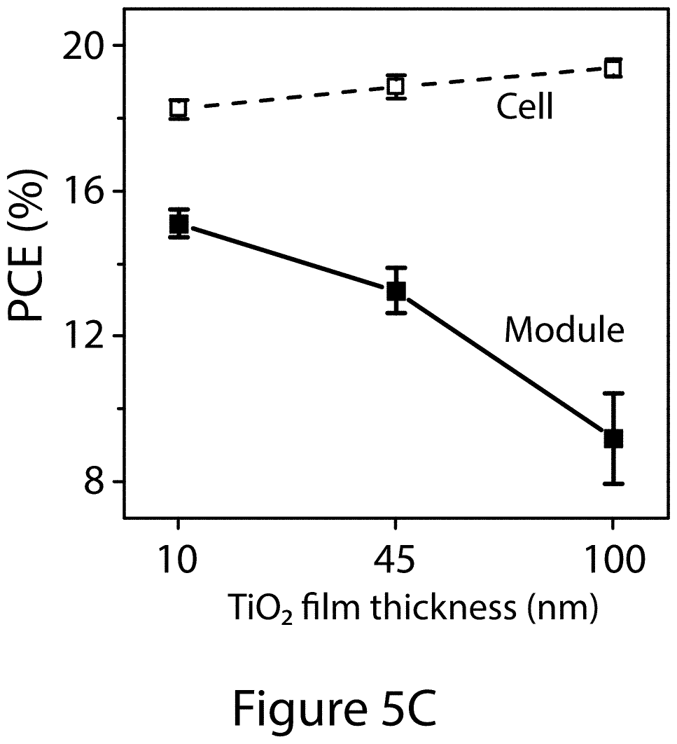

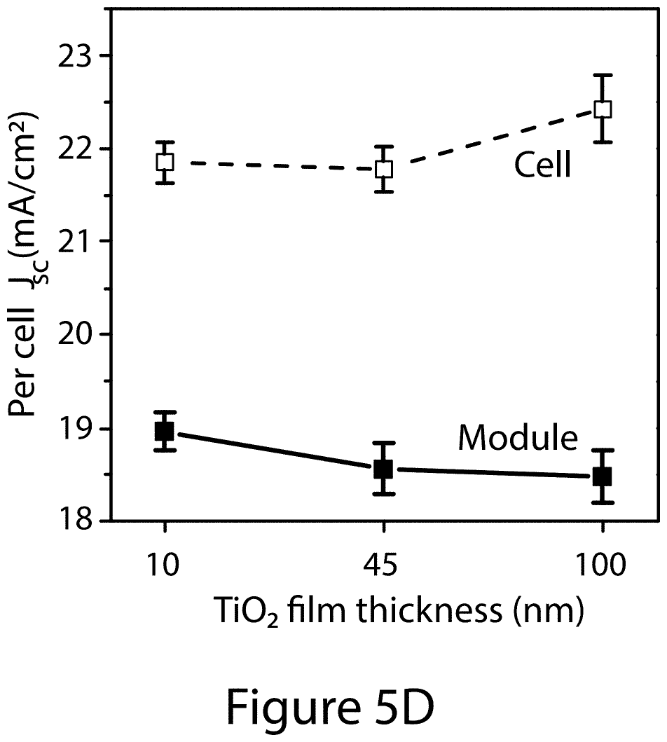

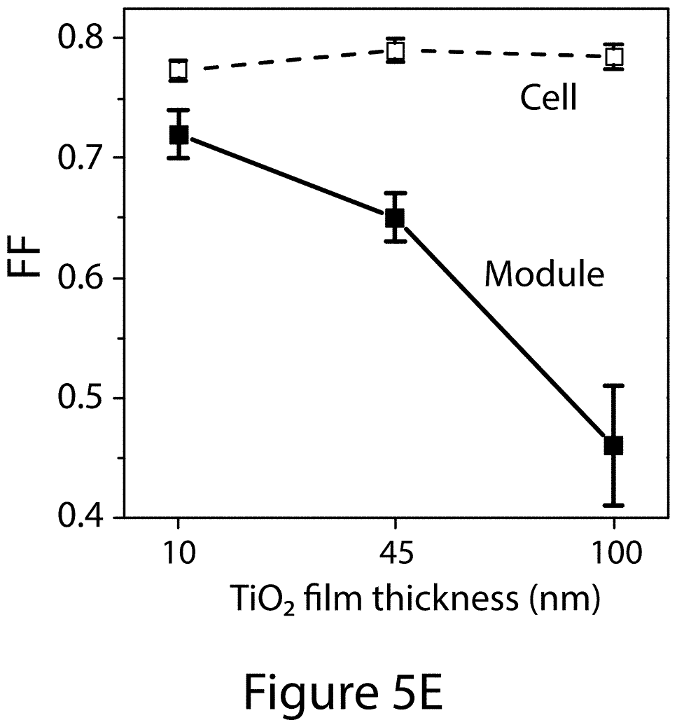

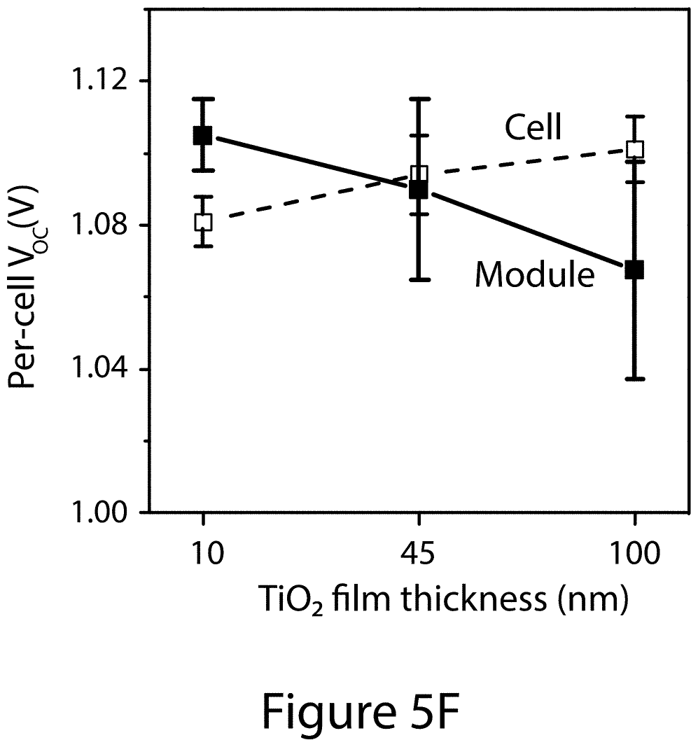

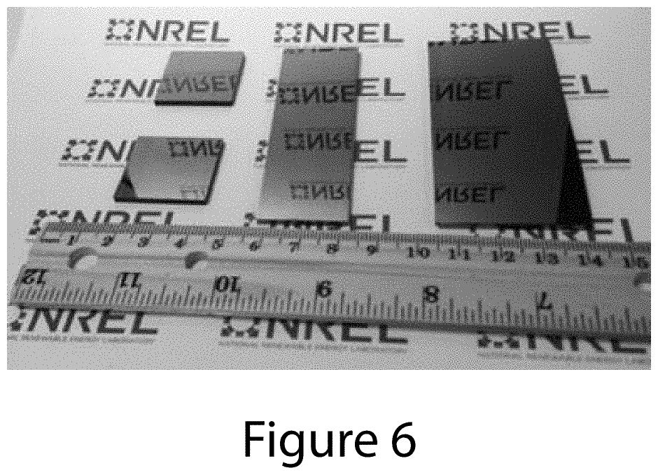

FIG. 5A shows the photocurrent-voltage (J-V) curves of MAPbI₃ perovskite modules having four individual cells series connected on a monolithic substrate. The modules were prepared using a liquid perovskite precursor composition and blade coating process. In some embodiments of the coating process, blade coating was performed on a Zehntner-Automatic film applicator coater using Zehntner ZUA 2000 blade at room temperature. The gap between the blade and the top substrate was fixed at 130 μm and the speed of coating was 5 mm/s. Once the precursor ink was dispensed on to the substrate by blade coating, the substrate was transferred into a diethyl ether bath for solvent extraction, after about 1 minute of drying. A perovskite film crystalized in the ether bath in about 1 minute. Further thermal annealing was conducted after the bath at 150° C. for about one to two minutes. Examples of the resultant blade-coated films are shown in FIG. 6. These modules have a device structure of FTO/c-TiO₂/perovskite/doped Spiro-OMeTAD/gold (corresponding to first contact layer/ETL/perovskite layer/HTL/second contact layer), with spiro-OMeTAD deposited by spin coating and a gold electrode deposited by thermal evaporation. Scribing was used to form gaps (e.g. P1—Reference number 290; P2—280; and P3—270 referring to FIG. 7 and FIG. 2B, respectively) to isolate and form interconnections between individual cells to complete the manufacture of the module on single substrate. A picture of the typical 4-cell mini-module is shown in the inset of FIG. 5A; the aperture area of this example module was about 10.36 cm². Optical microscopy images of typical P1, P2, and P3 scribing lines (gaps) are shown in FIG. 7, from which the geometrical fill factor or GFF of the module was estimated to be about 87.3%. The J-V curves (reverse scan) indicate that as the TiO₂ film (ETL) thickness was increased from 10 nm to 100 nm, the fill factor (FF) (where FF is defined as the maximum power point dived by the product of V_{OC} and I_{SC}) decreased significantly from about 0.720 to 0.465, without significant changes in the short-circuit current density (J_{sc}) and open-circuit voltage (V_{oc}), leading to the aperture PCE dropped from about 15.14% to 9.42%. Because these modules display moderate hysteresis—which will be discussed later—the stabilized power output (SPO) measurement under continuous one-sun illumination was also evaluated. Consistent with the PCE measured at J-V scans, the SPO efficiency also decreased from 14.7% to 8.6% when the TiO₂ film thickness was increased from about 10 nm to 100 nm. It is worth noting that the SPO efficiency was closer to the PCE resulting from the reverse scan J-V curves. The detailed J-V parameters along with SPO values are shown in Table 1.

TABLE 1
Effect of TiO₂ film (ETL) thickness on the PV parameters
of 4-cell perovskite mini-modules (aperture area ~10.36
cm²) under one-sun illumination.

| TiO₂ film | J_{sc} | V_{oc} | | PCE | SPO |
|---|---|---|---|---|---|
| (nm) | (mA/cm²) | (V) | FF | (%) | (%) |
| 10 | 4.80 | 4.381 | 0.720 | 15.14 | 14.7 |
| 45 | 4.73 | 4.338 | 0.639 | 13.12 | 12.3 |
| 100 | 4.71 | 4.303 | 0.465 | 9.42 | 8.6 |

The TiO₂ (ETL) film thickness significantly affected PV performances, with large differences in performances evident between the larger perovskite modules and the smaller lab-scale devices (˜0.1 cm² active area). The statistics of PV parameters for both modules and smaller-area devices (cells) are compared in FIGS. 5C, 5D, 5E, and 5F. For the purpose of comparison, the J_{sc} and V_{oc} values for the modules are shown on a per-cell basis. When the c-TiO₂ layer thickness was increased from about 10 nm to 100 nm, the PCE of the lab-scale devices improved from about 18.3% to 19.4%, which is mainly attributed to the increased J_{sc} and V_{oc}. In comparison to lab-scale devices, the J_{sc} of mini-modules was significantly lower, which may be attributed to the GFF of 87.3% corresponding to about 12.7% dead area resulting from the module interconnections. The V_{oc} values were comparable between the lab-scale devices and the larger modules. The biggest difference was the FF, which stayed almost unchanged around 0.77-0.79 for the lab-scale devices but decreased substantially from 0.72 to 0.46 when the c-TiO₂ film (ETL) thickness was increased from about 10 nm to 100 nm. This suggests that different factors need to be taken into consideration for device optimization when transitioning from smaller-area lab-scale cells to larger surface area modules, even when the same stack layers are used in both types of devices.

To understand the different TiO₂ ETL thickness dependence between smaller-area cells and larger area modules, it is necessary to examine how the perovskite modules are constructed in comparison to the standard process of constructing smaller-area devices. Referring again to FIGS. 2A and 2B, which show the schematics of a module 200 having an n-i-p architecture. Such a perovskite solar module 200 may include individual cells (e.g. 202A and 202B) serially interconnected on the same substrate 210. In some embodiments of the present disclosure, three scribing processes (P1, P2 and P3) may be needed to complete a module, corresponding to an ETL filled gap 290, a contact layer filled gap 280, and an empty gap 270, respectively. Each ETL filled gap may separate the first contact layer 220A of the first cell 202A from the first contact layer of the adjacent cell; e.g. first contact layer 220B of second cell 202B. Each contact layer filled gap 280 passing through the perovskite layer 240 enables the electrical connection of the first contact layer 220 with the second contact layer 260 of adjacent sub-cells (202A and 202B); each empty gap 270 may separate the second contact layer 260A of a first cell 202A from the second contact layer 260B of its adjacent second cell 202B. In a preferred situation, as shown in FIG. 2B, each contact layer filled gap 280 should scribe all the way through the electron transfer layer 230 to the top surface of the underlying first contact layer 220. Subsequent deposition of a second contact layer 260 (e.g., Au) may make direct contact with the first contact layer 220, forming the interconnections 204 between neighboring cells (202A and 202B). However, the TiO₂ ETL layer 230 may exhibit similar material hardness and optical properties as the underlying first contact layer 220 (e.g., FTO), which can present a challenge for both mechanical scribing and laser scribing for removing the oxide layer, without damaging the underlying TCO layer. Such a challenge may be similar for other oxides (e.g., ZnO and SnO₂) that may be used as ETLs in perovskite devices. Thus, in practice, a non-ideal interconnection in n-i-p perovskite modules may exists, where the second contact layer 260 is connected to the first contact layer 220 through a portion of the ETL 230 (see FIG. 2A). Because a module 200 includes multiple cells (e.g. 202A and 202B) with interconnections 204 and a large photocurrent is concentrated at the relatively narrow interconnections 204, the contact behavior at these interconnections becomes important to the operation of perovskite modules. In contrast, such interconnection 204 issues do not exist in small-area lab-scale devices.

FIG. 8 illustrates the contact behavior of FTO/TiO₂/Au only (no perovskite layer, HTL, etc.), which represents the actual materials of the interconnects used and tested in the perovskite module. These curves were generated by applying a voltage sweep of the FTO/TiO₂/Au and FTO/Au devices. The measurements were done under one-sun illumination through the glass side, mimicking the actual operating conditions of perovskite modules. The contact shows a clear diode rectification behavior when the TiO₂ (ETL) thickness was about 100 nm. This diode behavior changed to a resistive (ohmic) behavior as the TiO₂ film (ETL) thickness was reduced to about 10 nm. All of these interconnection contact resistances contributed to the series resistance of the module, leading to significant parasitic loss and contact voltage loss especially in view of a large current flowing through the multiple interconnection contacts within the module. Such parasitic and voltage loss is expected to strongly affect the FF and V_{oc} of the modules as observed in FIGS. 5E and 5F, respectively. PSCs may be based on a n-i-p device stack and/or on a p-i-n (inverted) device stack with either planar or mesoporous TiO₂ ETLs deposited on TCOs. Other oxides such as ZnO and NiO may also be used in either normal or inverted module structures. These oxides materials normally exhibit material hardness and optical property similar to the TCO substrates such as FTO and ITO. This presents a challenge for mechanical scribing or laser scribing for removing these materials due to the potential for damaging the underlying first contact layer 220 during the P2 scribing processing. The results presented herein suggest that any residual ETL, in this case an oxide layer, remaining after the P2 scribing may cause parasitic resistive losses in the final perovskite modules. Optimization of the oxide thickness for single cells versus larger surface area modules may be significantly different due to the interconnection resistive loss issues. Finally, it is worth noting that although the modules based on ˜10 nm TiO₂ ETL displayed good module performance, the resistance of FTO/TiO₂/Au contact, corresponding to the non-ideal case of FIG. 2A, was still about a factor of two larger than that of FTO/Au (without TiO₂ to simulate complete removal of the ETL), corresponding to the ideal case of FIG. 2B; this suggests that further improvement of module performance with higher FF can be expected with designs to fully address the interconnection contact issue.

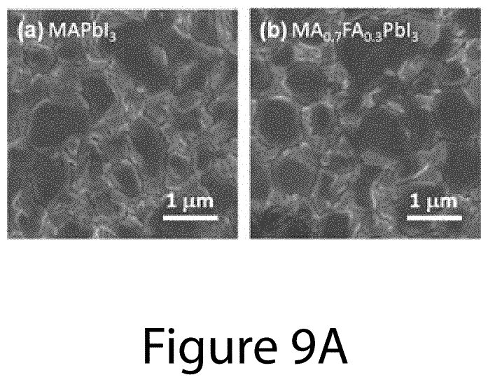

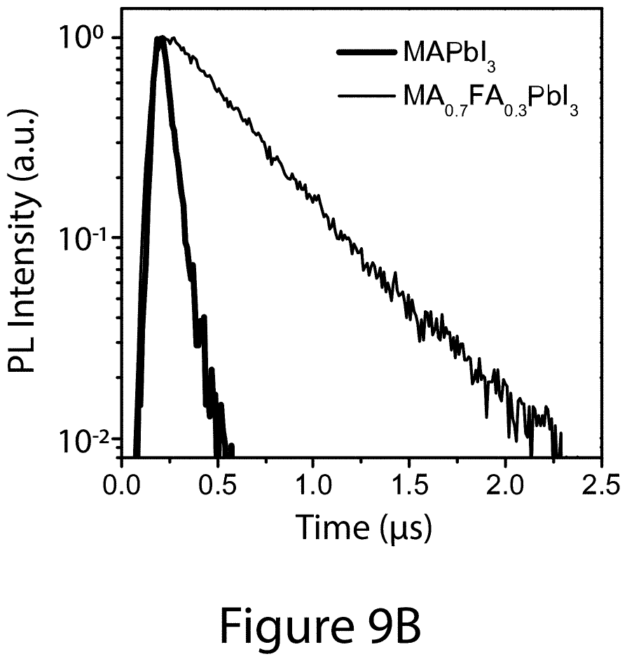

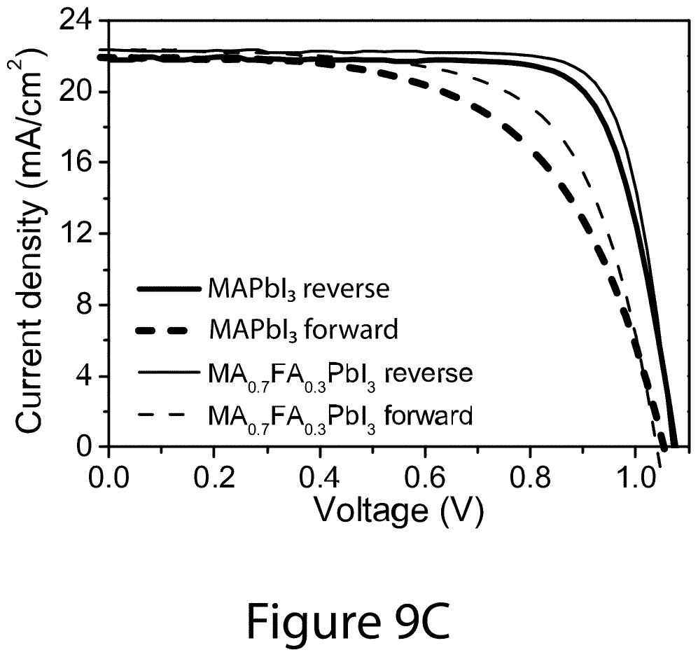

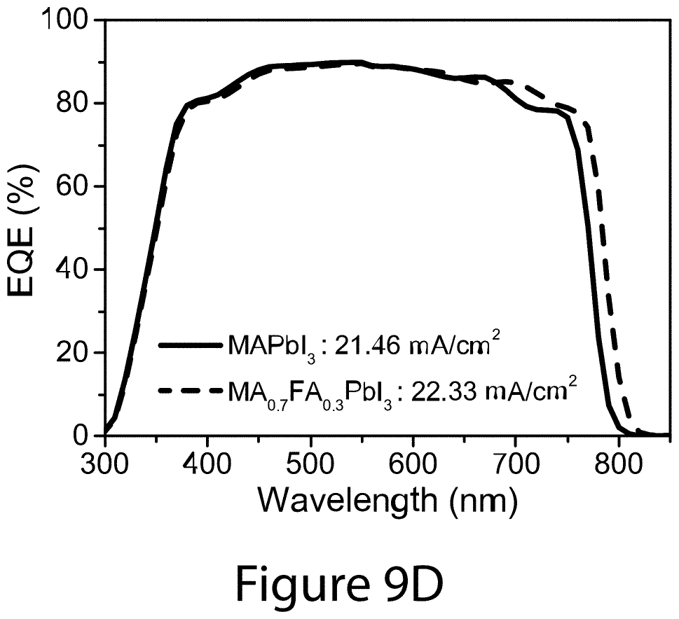

Composition engineering via A-site cation alloying (e.g., methylammonium—MA, formamidinium—FA, cesium) may improve the performance of perovskite solar cells. MA-FA alloying may result in the scalable deposition of perovskite thin films when assisted with the use of a heated substrate and the adjusting of the solvent composition may provide a wide processing window for blade coating processing method to manufacture high-quality perovskite thin films. Therefore, such solvent strategies were utilized with blade coating methods for producing mixed-cation perovskites. Panels (a) and (b) of FIG. 9A compare the top view SEM images of the MAPbI₃ and MA_{0.7}FA_{0.3}PbI₃ thin films prepared by using a blade coating approach. The grain morphology looks similar and both films were compact with no pinholes, which is important to ensure high-performance perovskite solar cells. The carrier lifetime of these two types of perovskite thin films were examined by TRPL measurement. FIG. 9B shows that MA_{0.7}FA_{0.3}PbI₃ has a much longer carrier lifetime than MAPbI₃ implying a reduced defect density with mixed cations.

Perovskite solar cells were prepared to compare the device characteristics. The typical J-V curves and EQE spectra of lab-scale PSCs (˜0.1 cm² active area) using MAPbI₃ and MA_{0.7}FA_{0.3}PbI₃ are compared in FIGS. 9C and 9D, respectively. In comparison to the MAPbI₃ PSC, the MA_{0.7}FA_{0.3}PbI₃ PSC shows improved PCE and reduced hysteresis. The detailed PV parameters are shown in Table 2. The PCE improvement is largely attributed to higher J_{sc} and FF with minimum change in V_{oc}. The higher J_{sc} for MA_{0.7}FA_{0.3}PbI₃ PSC is consistent with the improved EQE spectrum with a wider photo-response toward to the near infrared region. The long wavelength onset of EQE spectrum increases by about 16 nm when the perovskite composition was changed from MAPbI₃ to MA_{0.7}FA_{0.3}PbI₃, corresponding to about 30 meV reduction of the bandgap. Despite the smaller bandgap, the V_{oc} was only affected by a few mV, which is consistent with the reduced defect density observed for the MA_{0.7}FA_{0.3}PbI₃ perovskite composition shown by TRPL.

TABLE 2
PV parameters of PSCs based on MAPbI₃ and
MA_{0.7}FA_{0.3}PbI₃ perovskite thin films.

| | | J_{sc} | V_{oc} | | PCE |
|---|---|---|---|---|---|
| | | (mA/cm²) | (V) | FF | (%) |
| MAPbI₃ | Reverse | 21.88 | 1.075 | 0.769 | 18.08 |
| | Forward | 21.90 | 1.054 | 0.587 | 13.56 |
| MA_{0.7}FA_{0.3}PbI₃ | Reverse | 22.34 | 1.071 | 0.792 | 18.96 |
| | Forward | 22.38 | 1.045 | 0.655 | 15.32 |

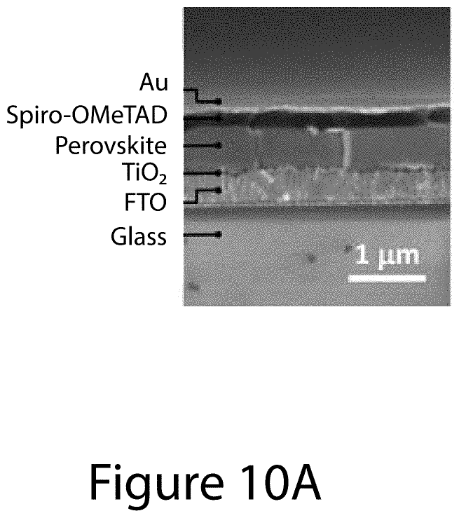

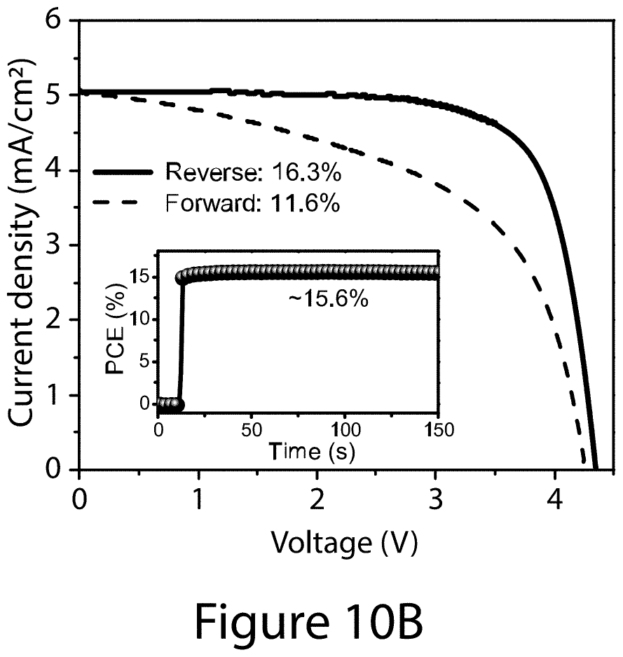

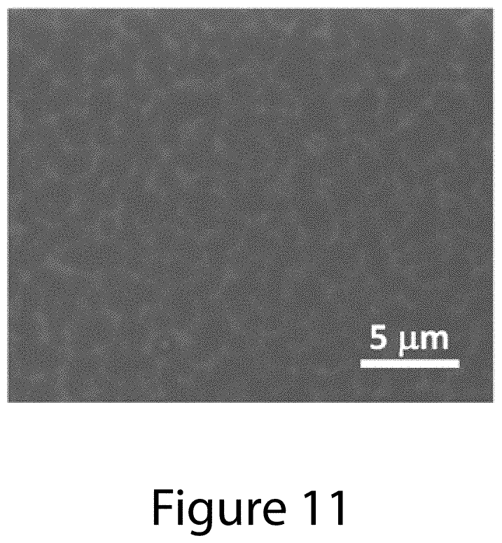

To achieve large scale production of perovskite modules, it is important to have fully scalable deposition methods for producing all device layers, including the perovskite active layer and the charge transport layers (e.g. ETL and HTL). For the PSC device structures used in this study, the TiO₂ ETL was prepared by spray pyrolysis, which is scalable and suitable for large area module fabrication. In addition, as described herein, blade coating was implemented to produce a spiro-OMeTAD HTL with a composition that is also useful for application using a spin coating process. The blade coating method using the spiro-OMeTAD composition performed well. An example of the HTL solution includes 72 mg 2,2′,7,7′-tetrakis(N,N-dip-methoxyphenylamine)-9,9′-spirobifluorene (Spiro-MeOTAD; Merck), 17 μL bis(trifluoromethane) sulfonimide lithium salt stock solution (520 mg Li-TFSI in 1 mL acetonitrile), and 29 μL 4-tert-butylpyridine (TBP), 20 μL FK102 Co(III) TFSI solution (300 mg/mL in acetonitrile), and 1 mL chlorobenzene solvent. FIG. 10A shows the cross-section SEM image of the full device stack consisting of spiro-OMeTAD HTL and MA_{0.7}FA_{0.3}PbI₃ perovskite layer both prepared by blade coating. The perovskite layer thickness is about 550 nm whereas the spiro-OMeTAD layer thickness is about 150-200 nm. The top view SEM image of the resultant blade-coated spiro-OMeTAD thin film is shown in FIG. 11. The film is continuous and pinhole-free. FIG. 10B shows the J-V curves (with both forward and reverse scans) of the best-performing four-cell perovskite module with blade coating applied perovskite layer and HTL. The aperture (˜10.36 cm²) PCE from reverse scan is about 16.3% with a J_{sc} of ˜5 mA/cm², V_{oc} of ˜4.35 V, and FF of ˜0.74. The corresponding per-cell J_{sc} and V_{oc} are ˜20 mA/cm² and 1.09 V, respectively. The V_{oc} value is very similar to that of the small-area (˜0.1 cm² active area) PSC (see FIG. 9C), which confirms the high quality of both the blade-coated perovskite and spiro-OMeTAD layer over the larger-area substrate. Since the module showed clear hysteresis with forward-scan PCE of ˜11.6% resulting mainly from the reduced FF (˜0.54), the stabilized PCE (or SPO) under continuous one-sun illumination was also studied. The stable (aperture) PCE reached about 15.6%, which is closer to the PCE determined from the reverse-scan J-V curve. It is worth noting that this aperture SPO efficiency of 15.6% was achieved with a geometrical fill factor of about 87.3% (see FIG. 5B), corresponding to an active-area module PCE of 17.9%. Since a module's GFF can be improved to >95% with modern scribing techniques, it may be expected that perovskite modules with aperture PCE >17% may also be achieved.

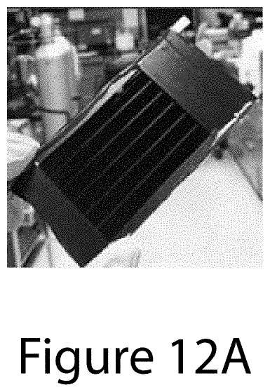

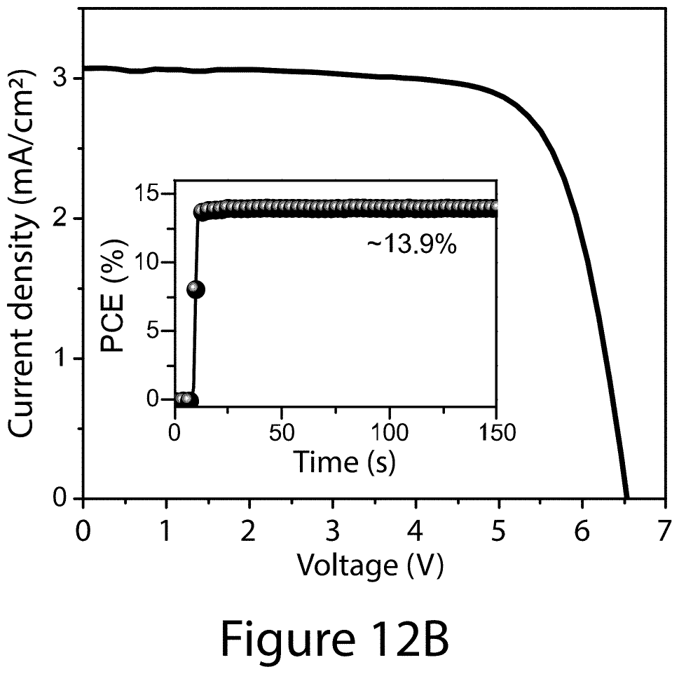

With the capability of fully scalable deposition of a perovskite-containing device stack, a six-cell module was manufactured with a ˜26 cm² aperture area, produced by blade coating of both the perovskite layer and HTL (see FIG. 12A.) This further demonstrates the feasibility of the scalable deposition techniques demonstrated herein for producing larger scale perovskite solar modules. This six-cell module shows an aperture PCE of ˜14.6% from reverse J-V scan (with J_{sc} of 3.07 mA/cm², V_{oc} of 6.54 V, and FF of 0.73) and the aperture SPO efficiency of ˜13.9% under continuous one-sun illumination (see FIG. 12B). The relatively low aperture SPO is in part caused a smaller GFF (˜83%) for this 26-cm² 6-cell perovskite module, corresponding to an active-area PCE of about 16.7%, which further confirms that blade coating of both the perovskite layer and the spiro-OMeTAD HTL is suitable for large scale perovskite module development.

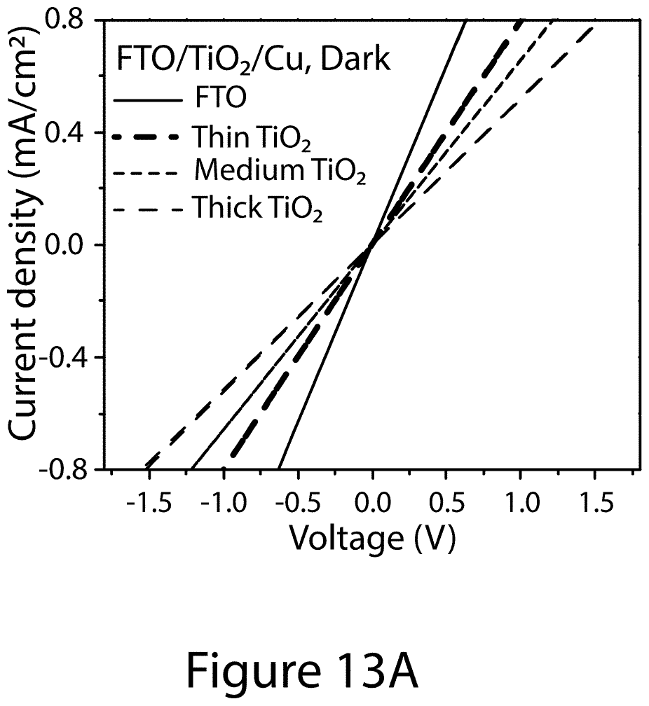

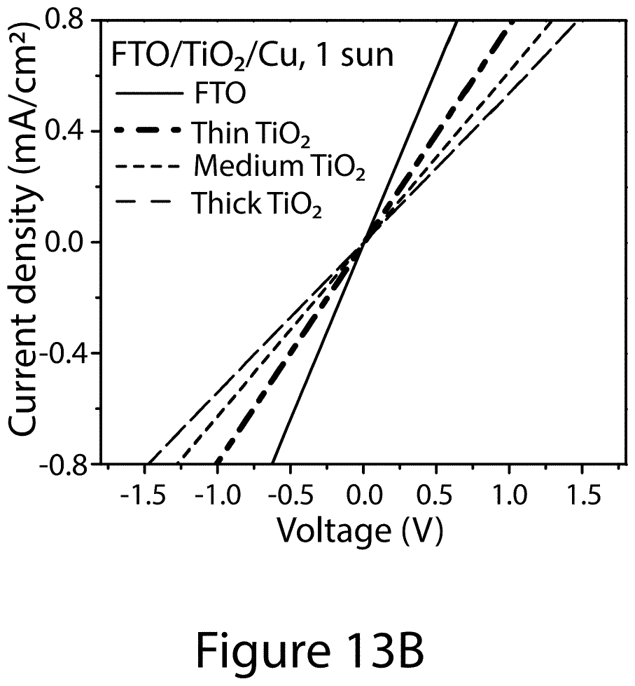

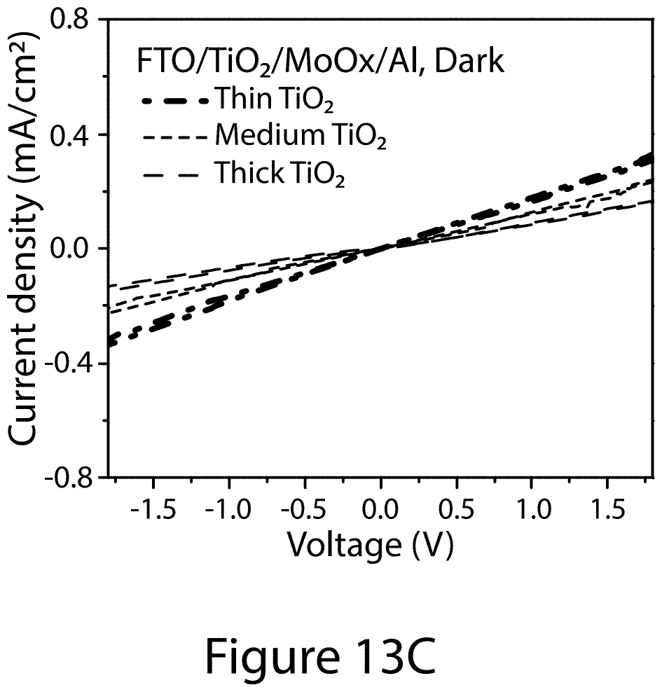

The impact of other second contact layer materials on the contact characteristics was also evaluated, with the results summarized in FIGS. 13A, 13B, and 13C. Interestingly, referring to FIGS. 13A and 13B, when copper was used to replace gold as the second contact layer material, the second contact layer demonstrated ohmic behavior regardless of the thickness of the underlying TiO₂ ETL. The resistance was also much reduced in comparison to the Au/TiO₂ (contact layer/ETL) combination. Also, the Cu/TiO₂ (contact layer/ETL) combination exhibited very minimum dependence on the illumination condition. FIG. 13C illustrates the contact behavior of FTO/TiO₂/MoOₓ/Al. Although the FTO/TiO₂/MoOₓ/Al also demonstrated ohmic contact behavior, the resistance was significantly larger than the silver and copper contacts layers.

As used herein, the term “substantially” refers to the inherent error involved in any numerical measurement. For example, a gap extending substantially through a thickness of layer refers to a gap that extends exactly through the thickness, a gap that extends almost entirely through the thickness, and a gap that extends entirely through the thickness and into the underlying substrate. The exact depth of the gap for the second and third cases will depend on the method used for forming the gap, e.g. laser scribing, mechanical scribing, and/or chemical etching, and are known to one of ordinary skill in the art of scribing photovoltaic materials and surfaces.

Experimental:

Organic-Inorganic Halide Perovskite film deposition. For blade coating, 42 wt % equimolar ratio MAI and PbI₂ precursors with 20% MACl additive in mixed solvent (NMP/DMF 55/45 weight ratio) were used. For mixed cations, 30% (molar ratio) FAI and 70% (molar ratio) MAI was used to replace MAI, and mixed solvent was adjusted to a higher DMF ratio (NMP/DMF 30/70 weight ratio). Blade coating was performed on a Zehntner-Automatic film applicator coater using Zehntner ZUA 2000 blade at room temperature inside a N₂-filled glovebox. The gap between blade and top substrate was fixed at 130 μm and the speed of coating was 5 mm/s. Once the precursor ink was dispensed on to the substrate by blade coating, the substrate was transferred into diethyl ether bath after about one minute of drying. Perovskite film crystalized in ether bath in 1 minute. A further thermal annealing was conducted after the bath at 150° C. with petri-dish covered for 75 seconds.

Device fabrication. For small area devices, a fluorine-doped tin oxide (FTO) substrate (TEC 7, Hartford Glass Co) was patterned using hydrogen evolution etching method (zinc powder and 5M HCl solution). For larger surface area modules (MMs), 1.5″×2″ TEC 7 substrates were laser-scribed (532 nm) with 7 mm spacing. Pre-patterned FTO was cleaned in base bath (0.2 M NaOH in ethanol) and then deposited with compact TiO₂ (c-TiO₂) layers of various thickness by spray pyrolysis using 0.2 M titanium diisopropoxide bis(acetylacetonate) in a 1-butanol solution at 450° C. The thickness of TiO₂ was controlled by the amount of sprayed solvent. Sprayed film was annealed at 450° C. for 1 hour. A thin C60 layer was deposited on the top of c-TiO₂. The concentrations of C60 SAM (1-material) were 1-1.5 mg/ml in mixed solvent (chlorobenzene/tetrahydrofuran=1/1 volume ratio). Blade coating was done with 2.5 mm/s speed with 130 μm gap and spin coating was done are 4000 rpm for 30 seconds. The perovskite film was subsequently coated before the deposition of the hole transport layer (HTL). The HTL solution was composed of 72 mg 2,2′,7,7′-tetrakis(N,N-dip-methoxyphenylamine)-9,9′-spirobifluorene (Spiro-MeOTAD; Merck), 17 μL bis(trifluoromethane) sulfonimide lithium salt stock solution (520 mg Li-TFSI in 1 mL acetonitrile), and 29 μL 4-tert-butylpyridine (TBP), 20 μL FK102 Co(III) TFSI solution (300 mg/mL in acetonitrile), and 1 mL chlorobenzene solvent. HTL was spin coated at 4,000 rpm for 35 seconds or blade coated at 130 μm gap with 10 mm/s speed. For MMs, the P2 gaps were scribed next to the P1 gaps using a mechanical scriber. A 100-nm Au layer was deposited on the HTL layer by thermal evaporation for top contact. For MMs, the P3 gaps were further performed next to the P2 gaps to isolate top contacts. Edges of MMs were further deleted, and copper foil tape was attached for external wiring.

Film characterizations. X-ray diffraction (XRD) of the perovskite thin films was performed using an X-ray diffractometer (Rigaku D/Max 2200) with Cu Kₐ radiation. Absorption spectra were carried out by an ultraviolet-visible (UV/Vis) spectrometer (Cary-6000i). SEM was taken by NOVA 630 NanoSEM, FEI. Contact resistance measurement was conducted on FTO/c-TiO₂/Au sandwiched structure using Keithley Source Meter (Model 2400) under one-sun condition.

Device characterizations. The J-V characteristics of the cells were obtained by using a Keithley Source Meter (Model 2400) under simulated one-sun AM 1.5G illumination at 100 mW cm ⁻² (Oriel Sol3A Class AAA Solar Simulator, Newport Corporation). A non-reflective shadow mask was used to define active area (0.12 cm² for small area and 10.36 cm² for MMs unless otherwise stated). External quantum efficiency (EQE) was measured using a solar cell quantum efficiency measurement system (QEX10, PV Measurements). Stabilized power output was monitored by a potentiostat (VersaSTAT MC, Princeton Applied Research) near a maximum power output point.

### EXAMPLES

### Example 1

A perovskite-containing solar cell module comprising: a glass substrate; a first cell; and a second cell, wherein: each cell comprises, in order: a first contact layer comprising fluorine-doped tin oxide, positioned on the substrate, and having an outside surface and a first thickness; an electron transfer layer comprising TiO₂ and having a second thickness between 1 nm and 10 μm; an active layer comprising the perovskite and having a third thickness; a hole transfer layer comprising Spiro-OMeTAD and having a fourth thickness; and a second contact layer comprising copper and having a fifth thickness, the first cell and the second cell are electrically connected by a first gap filled with the copper, and the first gap passes through the third thickness, the fourth thickness, and substantially through the second thickness to terminate at the outside surface.

### Example 2

A perovskite-containing solar cell module comprising: a substrate having a first surface;

a first cell; and a second cell, wherein: each cell comprises, in order: a first contact layer comprising a first material, positioned on the substrate, and having a second surface and a first thickness; an electron transfer layer (ETL) comprising a second material and having a second thickness; an active layer comprising the perovskite and having a third thickness; a hole transfer layer (HTL) comprising a third material and having a fourth thickness; and a second contact layer comprising a fourth material and having a fifth thickness, the first cell and the second cell are electrically connected by a first gap filled with the fourth material, and the first gap passes through the third thickness, the fourth thickness, and substantially through the second thickness to terminate at the second surface.

### Example 3

The solar cell module of Example 2, further comprising: a second gap filled with the second material, wherein: the second gap passes substantially through the first thickness to terminate at the first surface, and the second gap separates the first contact of the first cell from the first contact of the second cell.

### Example 4

The solar cell module of either Example 2 or 3, further comprising: a third gap, wherein the third gap passes through fourth thickness, the third thickness, and substantially through the second thickness to terminate at the second surface, and the third gap separates the second contact of the first cell from the second contact of the second cell.

### Example 5

The solar cell module of any one of Examples 2-4, further comprising: an insulating layer comprising a fifth material and positioned on the second contact layer, wherein: the second contact layer is positioned between the insulating layer and the HTL, the insulating layer is not electrically conductive, and the fifth material fills the third gap.

### Example 6

The solar cell module of any one of Examples 2-5, wherein: the perovskite is defined by ABX₃, A is a first cation, B is a second cation, and X is an anion.

### Example 7

The solar cell module of any one of Examples 2-6, wherein the first cation comprises at least one of an alkyl ammonium, formamidinium (FA), or cesium.

### Example 8

The solar cell module of any one of Examples 2-7, wherein the first cation comprises at least one of methylammonium (MA) or FA.

### Example 9

The solar cell module of any one of Examples 2-8, wherein the second cation comprises a metal.

### Example 10

The solar cell module of any one of Examples 2-9, wherein the metal comprises at least one of lead, tin, germanium, manganese, magnesium, zinc, cadmium, or a lanthanide.

### Example 11

The solar cell module of any one of Examples 2-10, wherein the anion comprises a halogen.

### Example 12

The solar cell module of any one of Examples 2-11, wherein the perovskite comprises at least one of MAPbI₃ or MAₓFA₁₋ₓPbI₃, wherein x is between zero and one, inclusively.

### Example 13

The solar cell module of any one of Examples 2-12, wherein the active layer is applied by a solution method.

### Example 14

The solar cell module of any one of Examples 2-13, wherein the solution method comprises blade coating.

### Example 15

The solar cell module of any one of Examples 2-14, wherein the first material comprises at least one of a metal nanowire, a carbon nanotube, a transparent conducting oxide, graphene, or PEDOT:PSS.

### Example 16

The solar cell module of any one of Examples 2-15, wherein the transparent conducting oxide comprises at least one of a fluorine-doped tin oxide, an indium-doped tin oxide, indium zinc oxide, gallium zinc oxide, or an aluminum-doped zinc oxide.

### Example 17

The solar cell module of any one of Examples 2-16, wherein the second material comprises oxygen.

### Example 18

The solar cell module of any one of Examples 2-17, wherein the second material comprises at least one of TiO₂, ZnO, SnO₂, BaSnO₃, or SrTiO₃.

### Example 19

The solar cell module of any one of Examples 2-18, wherein the ETL has a thickness between 5 nm and 10 μm.

### Example 20

The solar cell module of any one of Examples 2-19, wherein the ETL has a thickness between 5 nm and 1 μm.

### Example 21

The solar cell module of any one of Examples 2-20, wherein: the ETL further comprises a compact layer and a mesoporous layer, and the compact layer is positioned between the mesoporous layer and the first contact layer.

### Example 22

The solar cell module of any one of Examples 2-21, wherein the ETL is applied by a solution method.

### Example 23

The solar cell module of any one of Examples 2-22 wherein the solution method comprises spray pyrolysis.

### Example 24

The solar cell module of any one of Examples 2-23, wherein the third material comprises at least one of spiro-OMeTAD, PTAA, NiO, CuSCN, CuPc, CuI, a graphene oxide, a carbon nanotube, or any suitable organic material.

### Example 25

The solar cell module of any one of Examples 2-24, wherein the HTL is applied by a solution method.

### Example 26

The solar cell module of any one of Examples 2-25, wherein the solution method comprises blade coating.

### Example 27

The solar cell module of any one of Examples 2-26, wherein the fourth material comprises at least one of gold, silver, copper, aluminum, nickel, chromium, a molybdenum oxide, a carbon nanotube, graphene, or a transparent conducting oxide.

### Example 28

The solar cell module of any one of Examples 2-27, wherein the second contact layer has a thickness between 1 nm and 10 μm.

### Example 29

The solar cell module of any one of Examples 2-28, wherein the fifth material comprises a polymer.

### Example 30

A method for manufacturing a solar cell module, the method comprising: a first applying of a first solution of an electron transfer layer (ETL) precursor onto a first surface of a first contact layer having a first thickness, wherein: the first applying results in a first liquid film on the first surface, the first liquid film transforms into the ETL comprising a first solid material and having a second surface, and the first applying is performed using at least one of spin coating, spray coating, blade coating, slot-die coating, inkjet printing, screen printing, electrodeposition, sputtering, evaporation, pulsed laser deposition, chemical vapor deposition, or atomic layer deposition.

### Example 31

The method of Example 30, wherein the first applying is performed by spray coating.

### Example 32

The method of either Example 30 or 31, wherein the first applying is performed by spray pyrolysis.

### Example 33

The method of any one of Examples 30-32, wherein, during the first applying, the first surface is at a temperature between 300° C. and 600° C.

### Example 34

The method of any one of Examples 30-33, wherein the ETL precursor comprises titanium diisopropoxide bis(acetylacetonate).

### Example 35

The method of any one of Examples 30-34, wherein the first solution comprises the titanium diisopropoxide bis(acetylacetonate) and a solvent.

### Example 36

The method of any one of Examples 30-35, wherein the solvent comprises butanol.

### Example 37

The method of any one of Examples 30-36, wherein the first applying is performed at a rate between 0.005 mL/cm² to 0.5 mL/cm².

### Example 38

The method of any one of Examples 30-37, wherein the first solid material comprises TiO₂.

### Example 39

The method of any one of Examples 30-38, wherein the ETL has a second thickness between 1 nm and 100 nm.

### Example 40

The method of any one of Examples 30-39, wherein the second thickness between 1 nm and 10 nm.

### Example 41

The method of any one of Examples 30-40, wherein the first solid material is mesoporous.

### Example 42

The method of any one of Examples 30-41, further comprising a substrate, wherein the first contact layer is positioned between the substrate and the ETL.

### Example 43

The method of any one of Examples 30-42, further comprising, prior to the first applying, a first forming of a first gap, wherein the first gap passes substantially through the first thickness.

### Example 44

The method of any one of Examples 30-43, wherein the first forming is performed by at least one of mechanical scribing, laser scribing, or mechanical etching.

### Example 45

The method of any one of Examples 30-44, wherein the first gap has a width between 1 μm and 1 mm.

### Example 46

The method of any one of Examples 30-45, wherein: during the first applying, the first gap is filled with the ETL precursor, and after the first applying, the first gap is filled with the first solid material.

### Example 47

The method of any one of Examples 30-46, further comprising: after the first applying, a second applying of an active layer precursor solution onto the second surface, wherein: the second applying results in a second liquid film on the second surface.

### Example 48

The method of any one of Examples 30-47, wherein the active layer precursor solution comprises at least one of methylammonium iodide (MA), methylammonium chloride (MACI), formamidinium (FA), or lead iodide (PbI₂).

### Example 49

The method of any one of Examples 30-48, wherein the active layer precursor solution further comprises a polar solvent.

### Example 50

The method of any one of Examples 30-49, wherein the polar solvent comprises at least one of N-Methyl-2-pyrrolidone (NMP) or dimethylformamide (DMF).

### Example 51

The method of any one of Examples 30-50, wherein, during the second applying, the second liquid film transforms into an active layer.

### Example 52

The method of any one of Examples 30-51, further comprising: a first treating, wherein: the first treating transforms the second liquid film into an active layer by removing the polar solvent, and the active layer has a third thickness and a third surface.

### Example 53

The method of any one of Examples 30-52, wherein the first treating comprises at least one of thermal treating, liquid-liquid extraction, or exposure of the second liquid film to a gas.

### Example 54

The method of any one of Examples 30-53, wherein the thermal treating comprises heating the second liquid film to a temperature between 30° C. and 100° C.

### Example 55

The method of any one of Examples 30-54, wherein the liquid-liquid extraction comprises submerging the second liquid film in an extracting solvent, such that the polar solvent is transferred from the second liquid film to the extracting solvent.

### Example 56

The method of any one of Examples 30-55, wherein the extracting solvent comprises diethyl ether.

### Example 57

The method of any one of Examples 30-56, wherein the active layer comprises a perovskite having the composition ABX₃, where A is a first cation, B is a second cation, and X is an anion.

### Example 58

The method of any one of Examples 30-57, wherein the first cation comprises at least one of an alkyl ammonium, formamidinium (FA), or cesium.

### Example 59

The method of any one of Examples 30-58, wherein the first cation comprises at least one of methylammonium (MA) or FA.

### Example 60

The method of any one of Examples 30-59, wherein the second cation comprises a metal.

### Example 61

The method of any one of Examples 30-60, wherein the metal comprises at least one of lead, tin, germanium, manganese, magnesium, zinc, cadmium, or a lanthanide.

### Example 62

The method of any one of Examples 30-61, wherein the anion comprises a halogen.

### Example 63

The method of any one of Examples 30-62, wherein the perovskite comprises at least one of MAPbI₃ or MAₓFA₁₋ₓPbI₃, wherein x is between zero and one, inclusively.

### Example 64

The method of any one of Examples 30-63, wherein the second applying is performed by at least one of spraying, blade coating, curtain coating, dip coating, spin coating, slot-die coating, inkjet printing, or screen printing.

### Example 65

The method of any one of Examples 30-64, wherein the second applying is performed by blade coating.

### Example 66

The method of any one of Examples 30-65, wherein the blade coating is performed at a speed between 0.05 meters per min (m/min) and 1000 m/min.

### Example 67

The method of any one of Examples 30-66, wherein the blade coating is performed at a blade height between 10 μm and 400 μm.

### Example 68

The method of any one of Examples 30-67, wherein the active layer precursor solution is applied at a rate between 0.1 ml/m² and 50 ml/m².

### Example 69

The method of any one of Examples 30-68, wherein the blade coating forms the second liquid film having a film thickness between 1 μm and 20 μm.

### Example 70

The method of any one of Examples 30-69, further comprising: after the second applying, a third applying of a hole transfer layer (HTL) solution onto the third surface, wherein: the third applying results in a third liquid film on the third surface.

### Example 71

The method of any one of Examples 30-70, wherein the HTL solution comprises at least one of spiro-OMeTAD, PTAA, NiO, CuSCN, CuPc, graphene oxide, carbon nanotubes, or CuI.

### Example 72

The method of any one of Examples 30-71, wherein the HTL solution comprises spiro-OMeTAD.

### Example 73

The method of any one of Examples 30-72, wherein the HTL solution further comprises at least one of bis(trifluoromethane) sulfonimide, or 4-tert-butylpyridine.

### Example 74

The method of any one of Examples 30-73, wherein the HTL solution further comprises a solvent.

### Example 75

The method of any one of Examples 30-74, wherein the solvent comprises at least one of acetonitrile or chlorobenzene.

### Example 76

The method of any one of Examples 30-75, wherein, during the third applying, the third liquid film transforms into a HTL.

### Example 77

The method of any one of Examples 30-76, further comprising: a second treating, wherein: the second treating transforms the third liquid film into a HTL by removing the solvent, and the HTL has a fourth thickness and a fourth surface.

### Example 78

The method of any one of Examples 30-77, wherein the second treating comprises at least one of thermal treating, liquid-liquid extraction, or exposure of the second liquid film to a gas.

### Example 79

The method of any one of Examples 30-78, wherein the thermal treating comprises heating the third liquid film to a temperature between 30° C. and 100° C.

### Example 80

The method of any one of Examples 30-79, wherein the third applying is performed by at least one of spraying, blade coating, curtain coating, dip coating, spin coating, slot-die coating, inkjet printing, or screen printing.

### Example 81

The method of any one of Examples 30-80, wherein the third applying is performed by blade coating.

### Example 82

The method of any one of Examples 30-81, wherein the blade coating is performed at a speed between 0.05 meters per min (m/min) and 1000 m/min.

### Example 83

The method of any one of Examples 30-82, wherein the blade coating is performed at a blade height between 10 μm and 400 μm.

### Example 84

The method of any one of Examples 30-83, wherein the HTL precursor solution is applied at a rate between 0.1 ml/m² and 50 ml/m².

### Example 85

The method of any one of Examples 30-84, wherein the blade coating forms the third liquid film having a film thickness between 1 μm and 20 μm.

### Example 86

The method of any one of Examples 30-85, further comprising, after the second treating, a second forming of a second gap, wherein the second gap passes substantially through the third thickness and substantially through the second thickness.

### Example 87

The method of any one of Examples 30-86, wherein the second forming is performed by at least one of mechanical scribing, laser scribing, or mechanical etching.

### Example 88

The method of any one of Examples 30-87, wherein the second gap has a width between 1 μm and 1 mm.

### Example 89

The method of any one of Examples 30-88, further comprising, after the second forming, a fourth applying of a second contact layer comprising a second solid material onto the fourth surface, wherein the second contact layer has a fifth surface.

### Example 90

The method of any one of Examples 30-89, wherein the second solid material fills the second gap.

### Example 91

The method of any one of Examples 30-90, wherein the third applying is performed by a vapor deposition method.

### Example 92

The method of any one of Examples 30-91, wherein the vapor deposition method is thermal evaporation.

### Example 93

The method of any one of Examples 30-92, wherein the second material comprises a metal.

### Example 94

The method of any one of Examples 30-93, wherein the metal comprises at least one of gold, silver, or copper.

### Example 95

The method of any one of Examples 30-94, further comprising, after the fourth applying, a third forming of a third gap, wherein the third gap passes substantially through the third thickness and the fourth thickness and substantially through the second thickness.

### Example 96

The method of any one of Examples 30-95, wherein the fourth forming is performed by at least one of mechanical scribing, laser scribing, or mechanical etching.

### Example 97

The method of any one of Examples 30-96, wherein the third gap has a width between 1 μm and 1 mm.

### Example 98

The method of any one of Examples 30-97, further comprising after the third forming, a fifth applying of an insulating layer comprising a third solid material onto the fifth surface.

### Example 99

The method of any one of Examples 30-98, wherein the insulating layer comprises a polymer.

### Example 100

The method of any one of Examples 30-99, wherein the third solid material fills the third gap.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

1. A perovskite-containing solar cell module comprising:
a glass substrate;
a first cell; and
a second cell, wherein:
each cell comprises, in order:
a first contact layer comprising fluorine-doped tin oxide, positioned on the substrate, and having an outside surface and a first thickness;
an electron transfer layer comprising TiO₂ and having a second thickness between 1 nm and 10 μm;
an active layer comprising the perovskite and having a third thickness;
a hole transfer layer comprising Spiro-OMeTAD and having a fourth thickness; and
a second contact layer comprising copper and having a fifth thickness,
the first cell and the second cell are electrically connected by a first gap filled with the copper, and
the first gap passes through the third thickness, the fourth thickness, and substantially through the second thickness to terminate at the outside surface.

2. A perovskite-containing solar cell module comprising:
a substrate having a first surface;
a first cell; and
a second cell, wherein:
each cell comprises, in order:
a first contact layer comprising a first material, positioned on the substrate, and having a second surface and a first thickness;
an electron transfer layer (ETL) comprising a second material and having a second thickness;
an active layer comprising the perovskite and having a third thickness;
a hole transfer layer (HTL) comprising a third material and having a fourth thickness; and
a second contact layer comprising a fourth material and having a fifth thickness,
the first cell and the second cell are electrically connected by a first gap filled with the fourth material, and
the first gap passes through the third thickness, the fourth thickness, and substantially through the second thickness to terminate at the second surface.

3. The solar cell module of claim 2, further comprising:
a second gap filled with the second material, wherein:
the second gap passes substantially through the first thickness to terminate at the first surface, and
the second gap separates the first contact of the first cell from the first contact of the second cell.

4. The solar cell module of claim 3, further comprising:
a third gap, wherein
the third gap passes through fourth thickness, the third thickness, and substantially through the second thickness to terminate at the second surface, and
the third gap separates the second contact of the first cell from the second contact of the second cell.

5. The solar cell module of claim 4, further comprising:
an insulating layer comprising a fifth material and positioned on the second contact layer, wherein:
the second contact layer is positioned between the insulating layer and the HTL,
the insulating layer is not electrically conductive, and
the fifth material fills the third gap.

6. The solar cell module of claim 2, wherein:
the perovskite is defined by ABX₃,
A is a first cation,
B is a second cation, and
X is an anion.

7. The solar cell module of claim 2, wherein the perovskite comprises at least one of MAPbI₃ or MAₓFA₁₋ₓPbI₃, wherein x is between zero and one, inclusively.

8. The solar cell module of claim 2, wherein the first material comprises at least one of a metal nanowire, a carbon nanotube, a transparent conducting oxide, graphene, or PEDOT:PSS.

9. The solar cell module of claim 2, wherein the second material comprises at least one of TiO₂, ZnO, SnO₂, BaSnO₃, or SrTiO₃.

10. The solar cell module of claim 2, wherein the ETL has a thickness between 5 nm and 10 μm.

11. The solar cell module of claim 2, wherein:
the ETL further comprises a compact layer and a mesoporous layer, and
the compact layer is positioned between the mesoporous layer and the first contact layer.

12. The solar cell module of claim 2, wherein the third material comprises at least one of spiro-OMeTAD, PTAA, NiO, CuSCN, CuPc, CuI, a graphene oxide, a carbon nanotube, or any suitable organic material.

13. The solar cell module of claim 2, wherein the fourth material comprises at least one of gold, silver, copper, aluminum, nickel, chromium, a molybdenum oxide, a carbon nanotube, graphene, or a transparent conducting oxide.

14. The solar cell module of claim 2, wherein the second contact layer has a thickness between 1 nm and 10 μm.

15. The solar cell module of claim 5, wherein the fifth material comprises a polymer.

16. A method for manufacturing a solar cell module, the method comprising:
a first applying of a first solution of an electron transfer layer (ETL) precursor onto a first surface of a first contact layer having a first thickness, wherein:
the first applying results in a first liquid film on the first surface,
the first liquid film transforms into the ETL comprising a first solid material and having a second surface, and
the first applying is performed using at least one of spin coating, spray coating, blade coating, slot-die coating, inkjet printing, screen printing, electrodeposition, sputtering, evaporation, pulsed laser deposition, chemical vapor deposition, or atomic layer deposition.

17. The method of claim 16, wherein the first applying is performed by spray coating.

18. The method of claim 16, wherein the first applying is performed by spray pyrolysis.

19. The method of claim 16, wherein, during the first applying, the first surface is at a temperature between 300° C. and 600° C.

20. The method of claim 16, wherein the ETL precursor comprises titanium diisopropoxide bis(acetylacetonate).
